(19) United States
(12) Patent Application Publication
(10) Pub. No.: US 2013/0087842 A1
(43) Pub. Date: Apr. 11, 2013

(54) SEMICONDUCTOR DEVICES INCLUDING A VERTICAL CHANNEL TRANSISTOR AND METHODS OF FABRICATING THE SAME

(71) Applicants: Jiyoung KIM, Yongin-si (KR); Yongchul OH, Suwon-si (KR); Kyuhyun LEE, Hwaseong-si (KR); Hyun-Woo CHUNG, Seoul (KR); Gyoyoung JIN, Seoul (KR); HyeongSun HONG, Seongnam-si (KR); Yoosang HWANG, Suwon-si (KR)

(72) Inventors: Jiyoung KIM, Yongin-si (KR); Yongchul OH, Suwon-si (KR); Kyuhyun LEE, Hwaseong-si (KR); Hyun-Woo CHUNG, Seoul (KR); Gyoyoung JIN, Seoul (KR); HyeongSun HONG, Seongnam-si (KR); Yoosang HWANG, Suwon-si (KR)

(73) Assignee: SAMSUNG ELECTRONICS CO., LTD., Suwon-si (KR)

(21) Appl. No.: 13/614,457

(22) Filed: Sep. 13, 2012

(30) Foreign Application Priority Data
Oct. 11, 2011 (KR) 10-2011-0103500

(51) Int. Cl. H01L 29/78; H01L 27/108

(52) U.S. Cl. 257/306; 257/329; 257/E29.262; 257/E27.084

(57) ABSTRACT

According to example embodiments, a semiconductor device includes a lower active portion protruding from a substrate, an active pillar protruding from the lower active portion, a surround gate electrode surrounding the active pillar, a buried bit line extending along a first direction and being on the lower active portion and electrically connected to the lower active portion, and a contact gate electrode contacting both the surround gate electrode and a word line extending a second direction crossing the first direction.

### CROSS-REFERENCE TO RELATED APPLICATIONS

This U.S. non-provisional patent application claims priority under 35 U.S.C. §119 to Korean Patent Application No. 10-2011-0103500, filed on Oct. 11, 2011, in the Korean Intellectual Property Office, the entire contents of which are hereby incorporated by reference.

### BACKGROUND

Example embodiments of inventive concepts relate to a semiconductor device and a method of fabricating the same, and more particularly, to semiconductor devices including a vertical channel transistor and methods of fabricating the same.

Due to their small-sized, multifunctional, and/or low-cost characteristics, semiconductor devices are being esteemed as important elements in the electronic industry. Higher integration of semiconductor memory devices is desired to satisfy consumer demands for performance and prices. In the case of semiconductor memory devices, increased integration is desired because integration is an important factor in determining product prices. However, the expensive process equipment for increasing pattern fineness sets a practical limitation on increasing integration for semiconductor memory devices. To overcome such a limitation, there have been recently done a variety of studies on new technology for increasing integration density of the semiconductor memory device. For example, there has been suggested a vertical transistor having source and drain regions that are vertically spaced apart from each other by a vertical channel, especially, to realize a high density dynamic random access memory (DRAM) device.

### SUMMARY

Example embodiments of inventive concepts relate to a semiconductor device including a vertical transistor and having a reduced coupling noise property, and a method of fabricating the same.

According to example embodiments of inventive concepts, a semiconductor device may include: a lower active portion protruding from a substrate; a plurality of active pillars protruding from the lower active portion; surround gate electrodes surrounding the plurality of active pillars, respectively, with the surround gate electrodes being spaced apart from each other; a buried bit line extending between at least two pairs of neighboring surround gate electrodes, the buried bit line extending along a first direction and being electrically connected to the lower active portion; and a plurality of contact gate electrodes with each contact gate electrode contacting both of one of the surround gate electrodes and one of a plurality of word lines extending a second direction crossing the first direction.

The lower active portion may have one of a ‘T’-shape, a cross-like shape, and a diamond-like shape, in a plan view.

The plurality of contact gate electrodes may be between adjacent twosomes of the surround gate electrodes, respectively, and each one of the plurality of contact gate electrodes may be in contact with the surround gate electrodes of one of the adjacent twosomes of the surround gate electrodes.

A top surface of at least one of the plurality of active pillars may be higher than a top surface of at least one of the surround gate electrodes, and each one of the plurality of active pillars may include an upper doped region above a channel region.

The device may further include a lower doped region in the lower active portion, wherein the lower doped region is electrically connected to the buried bit line.

The lower doped region may not overlap the upper doped region, in terms of vertical level.

The buried bit line may contact the lower active portion, and the lower doped region may be in the lower active portion below the buried bit line.

The device may further include a bit line node contact between the buried bit line and the lower active portion. The lower doped region may be in the lower active portion below the bit line node contact.

The device may include a plurality of lower active portions, a plurality of buried bitlines, and a plurality of bitline node contacts. Each bitline node contact may be between one of the plurality of the lower active portions and one of the plurality of the buried bit lines.

The device may further include a plurality of storage node pads on the plurality of active pillars, respectively. A width of the plurality of storage node pads may be greater than a width of the plurality of active pillars.

At least one of the plurality of storage node pads may include a first side parallel to the first direction and a second side parallel to the second direction, and the second side may be longer than the first side.

The device may further include a data storing element connected to the storage node pad.

The device may further include a plurality of gate insulating layers, wherein the plurality of gate insulating layers are between the plurality of surround gate electrodes and the plurality of active pillars, respectively. The plurality of gate insulating layers may be between the plurality of surround gate electrodes and the lower active portion.

The device may further include a plurality of lower active portions and a device isolation layer between the plurality of lower active portions.

The lower active portion may have a ‘T’ shape in a plan view, and the buried bit line may vertically overlap an end portion of the lower active portion.

According to example embodiments of inventive concepts, a semiconductor device may include a lower active portion protruding from a substrate, an active pillar protruding from the lower active portion, a surround gate electrode surrounding the active pillar, a buried bit line extending along a first direction, the buried bit line being on the lower active portion and electrically connected to the lower active portion, and a contact gate electrode contacting both the surround gate electrode and a word line extending a second direction crossing the first direction.

According to example embodiments of inventive concepts, a method of fabricating a semiconductor device may include etching a substrate to form a lower active portion and a plurality of active pillars protruding from the lower active portion; forming surround gate electrodes spaced apart from each other to surround the active pillars, respectively; forming a buried bit line extending along a first direction, the buried bit line being disposed between adjacent ones of the surround gate electrodes and electrically connected to the lower active portion; forming a contact gate electrode being in contact with the surround gate electrode; and forming a word line being in contact with the contact gate electrode and extending a second direction crossing the first direction.

The method may further include forming an upper doped region in an upper region of the active pillar, and forming a lower doped region in the lower active portion.

The upper doped region and the lower doped region may be simultaneously formed before the formation of the buried bit line.

The lower doped region may be formed after the formation of the buried bit line.

According to example embodiments of inventive concepts, a semiconductor device includes a plurality of transistor pairs on a substrate. Each transistor pair includes a first active pillar surrounded by a first gate electrode, a second active pillar spaced apart from the first active pillar and surrounded by a second gate electrode, and a contact gate electrode connecting the first and second gate electrodes. The device further includes a plurality of impurity regions spaced apart in the substrate and a plurality of bitlines intersecting a plurality of wordlines. Each bitline is connected to at least one of the impurity regions and each bitline extends in a first direction between the first and second gate electrodes of at least one of the transistor pairs. Each wordline is connected to at least one contact gate electrode of the plurality of transistor pairs.

The substrate may include a plurality of active portions spaced apart and protruding from the substrate. Each of the plurality of active portions may contain one of the impurity regions. Each of the plurality of active portions may connect one of an adjacent two of the first active pillars and an adjacent two of the second active pillars.

The device may further include an isolation layer between the plurality of active portions, wherein each contact gate electrode of the plurality of transistor pairs is over the isolation layer.

The plurality of transistor pairs may include a first transistor pair and a second transistor pair. One of the plurality of impurity regions may be connected through the substrate to the first active pillar of the first pair and the first active pillar of the second transistor pair.

Each of the plurality of transistor pairs may include a gate oxide layer that extends between the first active pillar and the first gate electrode and between the second active pillar and the second gate electrode. Each of the first active pillars of the plurality of transistor pairs may include a doped region above a channel region, and the first gate electrodes in each of the plurality of transistor pairs may surround the channel regions but not the doped regions of the first active pillars.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a circuit diagram schematically illustrating vertical channel transistors of a semiconductor device according to example embodiments of inventive concepts;

FIG. 2A is a plan view of a semiconductor device according to example embodiments of inventive concepts;

FIG. 2B shows sectional views taken along lines A-A′, B-B′, C-C′ and D-D′ of FIG. 2A;

FIG. 2C is a perspective view of the semiconductor device according to the example embodiments of inventive concepts;

FIG. 3A is a sectional view taken along a line A-A′ of FIG. 2B and schematically showing technical effect of inventive concepts;

FIG. 3B is a perspective view exemplarily illustrating a flow of electrons in the semiconductor device of FIG. 2C;

FIGS. 4A through 12A are plan views sequentially illustrating an example process of fabricating the semiconductor device of FIG. 2A.

FIGS. 4B, 4C, 5B, 6B, 6C, 7B, 7C, 8B, 8C, 9B, 10B, 11B, and 12B are sectional views taken along lines A-A′, B-B′, C-C′ and D-D′ of FIGS. 4A through 12A, respectively;

FIG. 13A is a plan view of a semiconductor device according to example embodiments of inventive concepts;

FIG. 13B shows sectional views taken along lines A-A′, B-B′, C-C′ and D-D′ of FIG. 13A;

FIG. 13C is a perspective view of the semiconductor device according to example embodiments of inventive concepts;

FIG. 14A is a plan view of a semiconductor device according to example embodiments of inventive concepts;

FIG. 14B shows sectional views taken along lines A-A′, B-B′, C-C′ and D-D′ of FIG. 14A;

FIG. 15A is a plan view of a semiconductor device according to example embodiments of inventive concepts;

FIG. 15B shows sectional views taken along lines A-A′, B-B′, C-C′ and D-D′ of FIG. 15A;

FIG. 16A is a plan view of a semiconductor device according to example embodiments of inventive concepts;

FIG. 16B shows sectional views taken along lines A-A′, B-B′, C-C′ and D-D′ of FIG. 16A;

FIG. 17A is a plan view of a semiconductor device according to example embodiments of inventive concepts;

FIG. 17B shows sectional views taken along lines A-A′, B-B′, C-C′ and D-D′ of FIG. 17A;

FIG. 18A is a plan view of a semiconductor device according to example embodiments of inventive concepts;

FIG. 18B shows sectional views taken along lines E-E′, F-F′, G-G′ and H-H′ of FIG. 18A;

FIGS. 18C and 18D are plan views of semiconductor devices according to example embodiments of inventive concepts;

FIG. 19A is a plan view of a semiconductor device according to example embodiments of inventive concepts;

FIG. 19B shows sectional views taken along lines E-E′, F-F′, G-G′ and H-H′ of FIG. 19A;

FIGS. 19C and 19D are plan views of semiconductor devices according to example embodiments of inventive concepts;

FIG. 20 is a block diagram schematically illustrating electronic devices including a semiconductor device according to example embodiments of inventive concepts; and

FIG. 21 is a block diagram schematically illustrating memory systems including a semiconductor device according to example embodiments of inventive concepts.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. Like reference characters refer to the same parts throughout the different views.

### DETAILED DESCRIPTION

Example embodiments of inventive concepts will now be described more fully with reference to the accompanying drawings, in which some example embodiments are shown. Example embodiments of inventive concepts may, however, be embodied in many different forms and should not be construed as being limited to the embodiments set forth herein; rather, these embodiments are provided so that this disclosure will be thorough and complete, and will fully convey the scope of example embodiments of inventive concepts to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

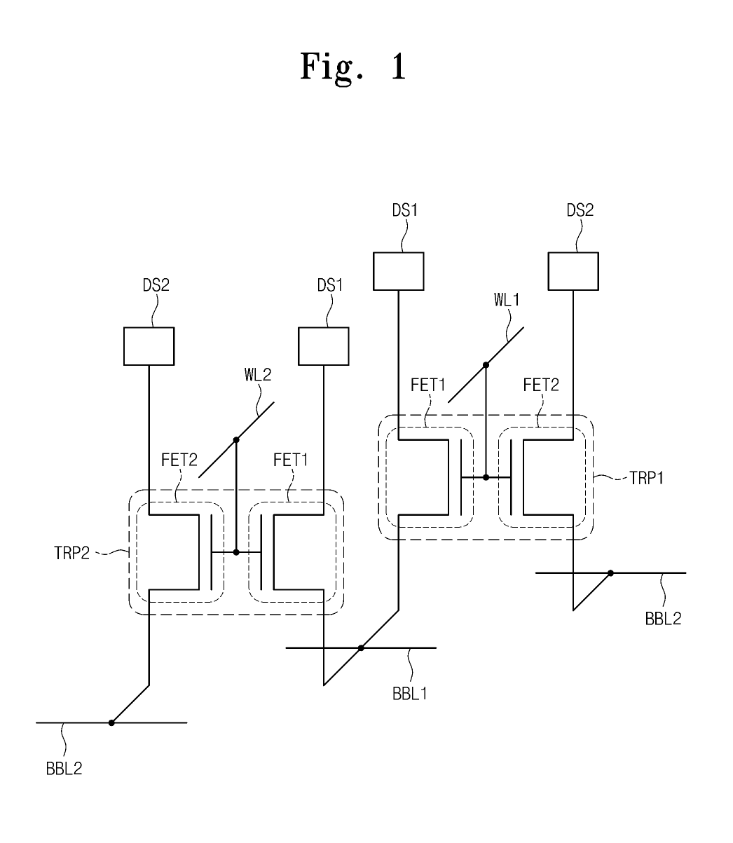

FIG. 1 is a circuit diagram schematically illustrating vertical channel transistors of a semiconductor device according to example embodiments of inventive concepts.

Referring to FIG. 1, a semiconductor device according to example embodiments of inventive concepts may include a plurality of transistor-pairs TRP1 and TRP2. For example, as shown in FIG. 1, the semiconductor device may include a first transistor-pair TRP1 and a second transistor-pair TRP2 that are disposed adjacent to each other. Each of the first and second transistor-pairs TRP1 and TRP2 may include a first vertical channel transistor FET1 and a second vertical channel transistor FET2. Gates of the first and second vertical channel transistors FET1 and FET2 of the first transistor-pair TRP1 may be electrically connected to a first word line WL1. In other words, the first and second vertical channel transistors FET1 and FET2 of the first transistor-pair TRP1 may share the first word line WL1. Gates of the first and second vertical channel transistors FET1 and FET2 of the second transistor-pair TRP2 may share a second word line WL2. The first word line WL1 and the second word line WL2 may be configured in such a way that they can be independently controlled.

A drain electrode of the first vertical channel transistor FET1 may be electrically connected to a first buried bit line BBL1, a drain electrode of the second vertical channel transistor FET2 may be electrically connected to a second buried bit line BBL2. The first and second buried bit lines BBL1 and BBL2 may be configured in such a way that they can be independently controlled. The first and second word lines WL1 and WL2 may cross the first and second buried bit lines BBL1 and BBL2. A pair of the first vertical channel transistors FET1, which are disposed in the first and second transistor-pairs TRP1 and TRP2, respectively, may share the first buried bit line BBL1. Similarly, a pair of the second vertical channel transistors FET2, which are disposed in the first transistor-pair TRP1 and a third transistor-pair (not shown), respectively, may share the second buried bit line BBL2. the first and second buried bit lines BBL1 and BBL2 may serve as bit lines coupled to a sense amplifier.

In sum, the first and second vertical channel transistors FET1 and FET2, which are included in each of the transistor-pairs TRP1 and TRP2, may share one of the word lines WL1 and WL2 and be electrically connected to different ones of the buried bit lines BBL1 and BBL2, respectively. In addition, each of the buried bit lines BBL1 and BBL2 may be shared by a pair of the transistor-pairs adjacent to each other.

First data storing elements DS1 may be electrically coupled to source electrodes of the first vertical channel transistors FET1, respectively, and second data storing elements DS2 may be electrically coupled to source electrodes of the second vertical channel transistors FET2, respectively. The first vertical channel transistor FET1 and the first data storing element DS1 may be included in a unit memory cell, and similarly, the second vertical channel transistor FET2 and the second data storing element DS2 may be included in another unit memory cell. Each of the first and second vertical channel transistors FET1 and FET2 may serve as switching devices controlling electric connections between the first and second data storing elements DS1 and DS2 and the first and second buried bit lines BBL1 and BBL2. That is, each of the transistor-pairs TRP1 and TRP2 and each of the first and second data storing elements DS1 and DSG2 coupled thereto may constitute a pair of unit memory cells. Various types of memory elements can be used for the first and second data storing elements DS1 and DS2. For example, the first and second data storing elements DS1 and DS2 may be realized using one of a capacitor, a magnetic tunnel junction (MTJ) pattern, or a variable resistance structure. In other words, the semiconductor device according to example embodiments of inventive concepts may be realized as one of a volatile memory device, a nonvolatile memory device, a magnetic memory device, or a resistive memory device. But example embodiments of inventive concepts may not be limited thereto.

Hereinafter, semiconductor devices according to the example embodiments of inventive concepts and methods of fabricating the same will be described in more detail with reference to the accompanying drawings.

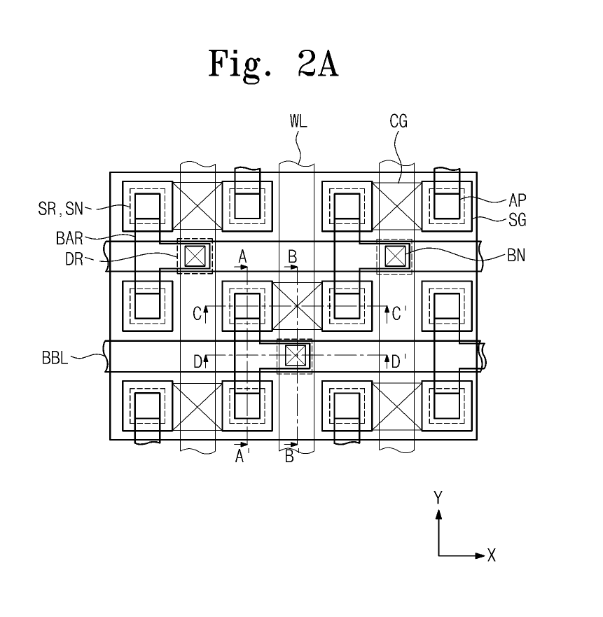

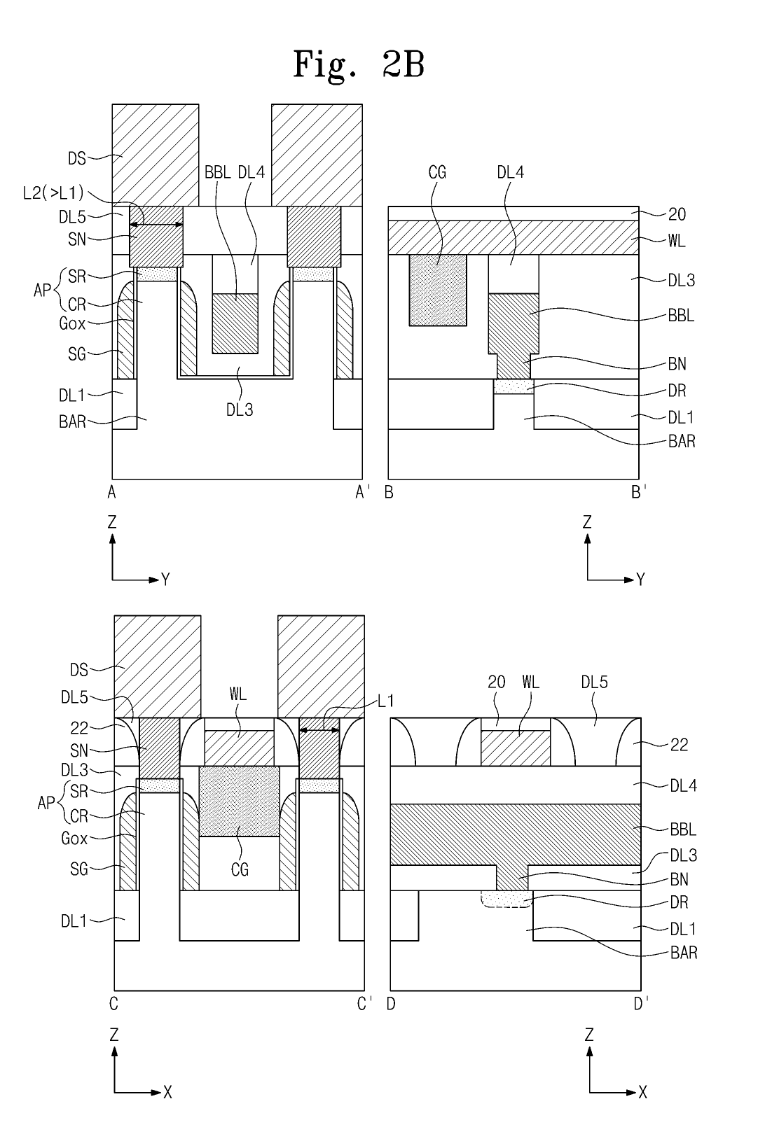

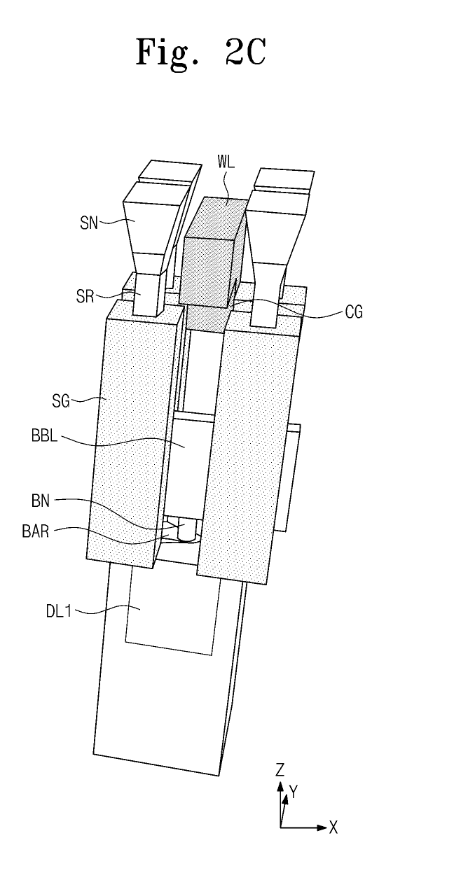

FIG. 2A is a plan view of a semiconductor device according to example embodiments of inventive concepts, and FIG. 2B shows sectional views taken along lines A-A′, B-B′, C-C′ and D-D′ of FIG. 2A. FIG. 2C is a perspective view of the semiconductor device according to example embodiments of inventive concepts.

Referring to FIGS. 2A, 2B and 2C, a semiconductor device according to example embodiments of inventive concepts may include a plurality of lower active portions BAR protruding from a substrate 1. The lower active portions BAR may be separated from each other by a device isolation layer DL1 interposed therebetween. Each of the lower active portions BAR may be formed to have a ‘T’-shaped structure in a plan view. There may be a plurality of active pillars AP protruding from each of the lower active portions BAR. The active pillar AP and the lower active portion BAR may include the same material as the substrate 1. Each of the active pillars AP may be surrounded by a surround gate electrode SG, which may include a conductive layer. An upper portion of the active pillar AP may be exposed by the surround gate electrode SG. Each of the active pillars AP may include an upper doped region SR, which may be formed in the exposed upper portion, and a channel region CR, which may be located below the upper doped region SR and be surrounded by the surround gate electrode SG. The upper doped region SR may be doped with, for example, n-type impurities, but example embodiments of inventive concepts are not limited thereto.

A gate insulating layer Gox may be interposed between the active pillar AP and the surround gate electrode SG. The gate insulating layer Gox may extend to be interposed between the surround gate electrode SG and the lower active portion BAR. The gate insulating layer Gox may include a layer of, for example, silicon oxide. On the lower active portion BAR, there may be a buried bit line BBL located between adjacent ones of the surround gate electrodes SG. The buried bit line BBL may be disposed to extend along a first direction X. the buried bit line BBL may be electrically connected to the lower active portion BAR via a bit line node contact BN interposed between the buried bit line BBL and the lower active portion BAR. Each of the buried bit line BBL and the bit line node contact BN may include a conductive layer. A lower doped region DR may be provided in the lower active portion BAR below the bit line node contact BN. The lower doped region DR may not overlap the active pillar AP in a vertical level. the lower doped region DR may be doped with, for example, n-type impurities.

A first insulating layer DL3 may be provided to sidewalls of cover the surround gate electrodes SG, a sidewall and bottom surface of the buried bit line BBL, and a sidewall of the bit line node contact BN. A top surface of the buried bit line BBL may be covered with a second insulating layer DL4. Top surfaces of the first and second insulating layers DL3 and DL4 may be coplanar with each other and be located at a level that is higher than that of the active pillar AP. A word line WL may be disposed on the first insulating layer DL3 and the second insulating layer DL4 to cross the buried bit line BBL. In other words, the word line WL may extend along a second direction Y crossing the first direction X. A sidewall of the word line WL may be covered with a spacer 22, and a top surface of the word line WL may be covered with a capping layer 20. The active pillar AP may extend along a third direction Z intersecting or orthogonal to both of the first and second directions X and Y. A contact gate electrode CG may be disposed in the first insulating layer DL3 to be in contact with both of the word line WL and the surround gate electrode SG. The contact gate electrode CG may extend along the third direction Z. The contact gate electrode CG may be in contact with both of two surround gate electrodes SG adjacent to each other, but be separated from the buried bit line BBL. A third insulating layer DL5 may be provided on the second insulating layer DL4 to fill a space between adjacent ones of the word lines WL. Each of the word line WL and the contact gate electrode CG may include a conductive layer. Each of the spacer 22, the capping layer 20, and the first to third insulating layers DL3, DL4 and DL5 may include an insulating layer, such as a silicon oxide layer, a silicon nitride layer, or a silicon oxynitride layer.

A storage node pad SN may be in contact with the upper doped region SR through the third insulating layer DL5 and the first insulating layer DL3. The storage node pad SN may include a doped polysilicon layer or a metal-containing layer. The storage node pad SN may be formed to have a width greater than the active pillar AP. For example, the storage node pad SN may have a first side L1 parallel to the word line WL and a second side L2 parallel to the buried bit line BBL, and a width L2 of the second side may be greater than a width L1 of the first side. The width L2 of the second side may be greater than a width of the active pillar AP. Data storing elements DS may be provided on the storage node pads SN, respectively.

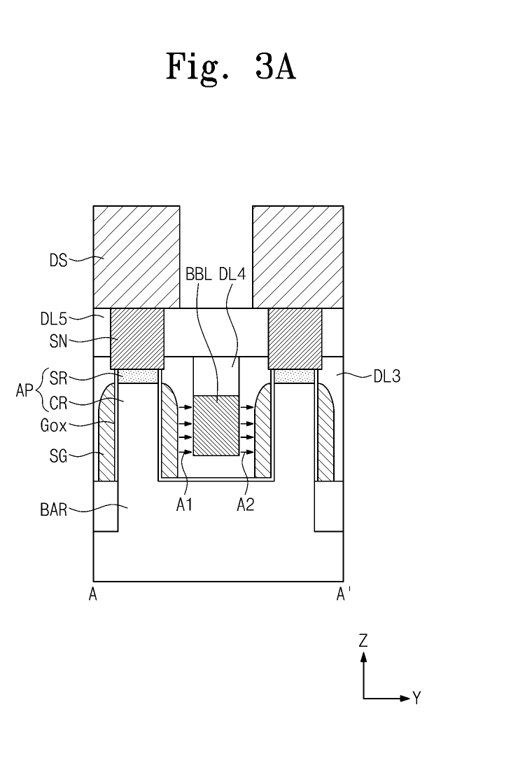

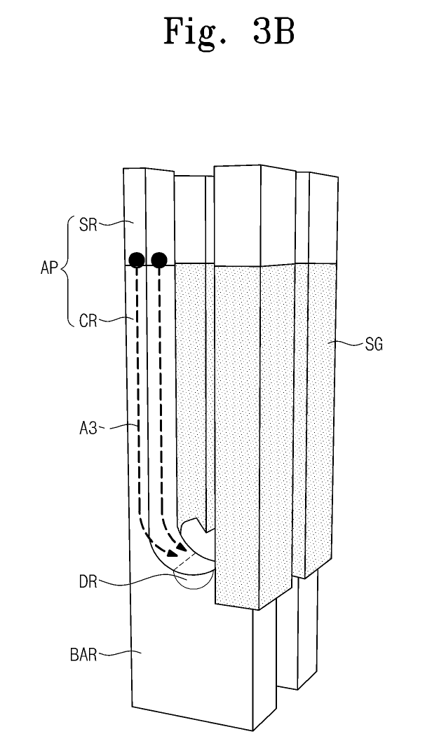

FIG. 3A is a sectional view schematically showing technical effect of inventive concepts and taken along a line A-A′ of FIG. 2B.

Referring to FIG. 3A, the buried bit line BBL may be provided between adjacent ones of the surround gate electrodes SG. By contrast, if the buried bit line BBL is not disposed between adjacent ones of the surround gate electrodes SG, the surround gate electrodes SG adjacent to each other may be electromagnetically coupled with each other as depicted by first arrows A1, and thus, a voltage applied to one thereof may result in a fluctuation in electric potential of other adjacent one. However, according to example embodiments of inventive concepts, the conductive buried bit line BBL interposed between adjacent ones of the surround gate electrodes SG may serve as an shielding structure that prevents the afore-described electromagnetic coupling from occurring between the adjacent ones of the surround gate electrodes SG. That is, it is possible to suppress a coupling noise from occurring between the adjacent ones of the surround gate electrodes SG.

According to example embodiments of inventive concepts, as depicted by second arrows A2, the channel region CR of the active pillar AP may be electrically affected by a voltage applied to the buried bit line BBL. However, this coupling noise can be limited (and/or prevented) due to the presence of the surround gate electrode SG surrounding the channel region CR.

FIG. 3B is a perspective view exemplarily illustrating a flow of electrons in an active pillar of the semiconductor device of FIG. 2C.

Referring to FIG. 3B, for the semiconductor device according to example embodiments of inventive concepts, the surround gate electrode SG is formed to surround the whole sidewall of the active pillar. This enables to increase an on-current of the transistor and improve a sub-threshold property of the transistor. Furthermore, the lower doped region DR may not overlap the active pillar AP in a vertical level. Electric charges may be moved from the upper doped region SR to the lower doped region DR along third arrows A3. Accordingly, the channel region CR of the active pillar AP may be connected to the substrate thereunder and be limited (and/or prevented) from being electrically floated.

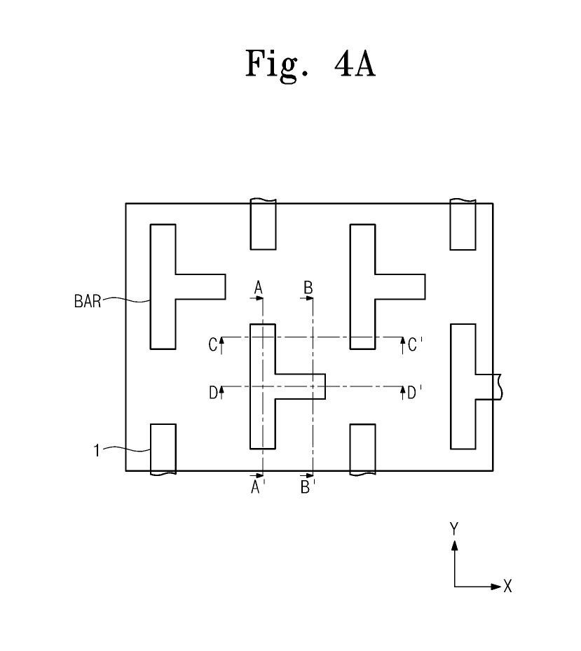

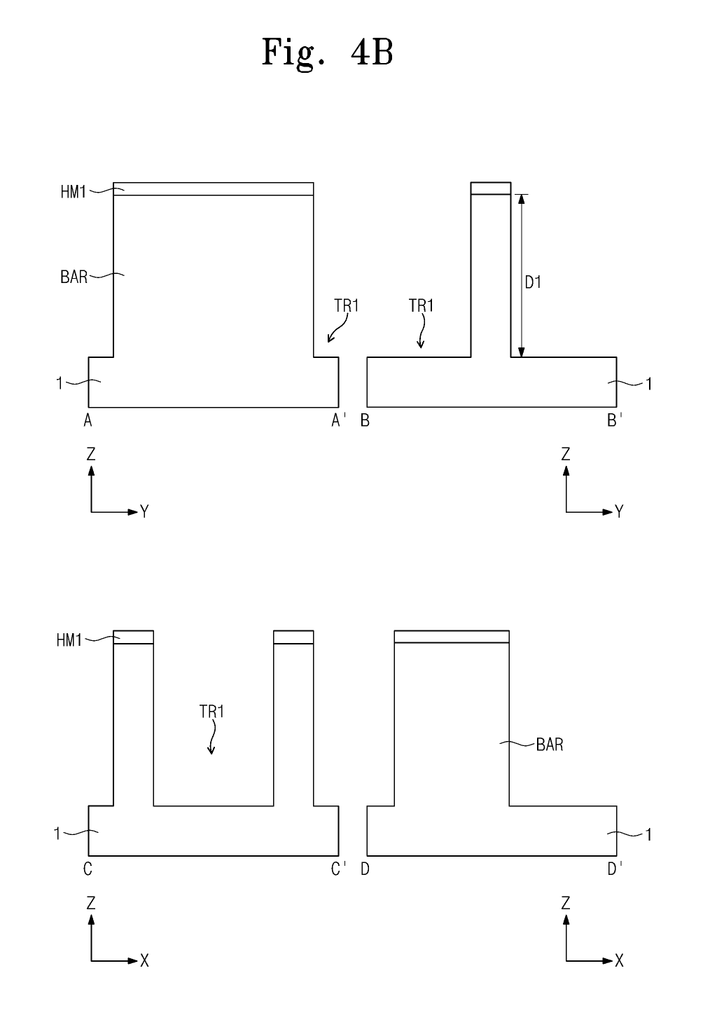

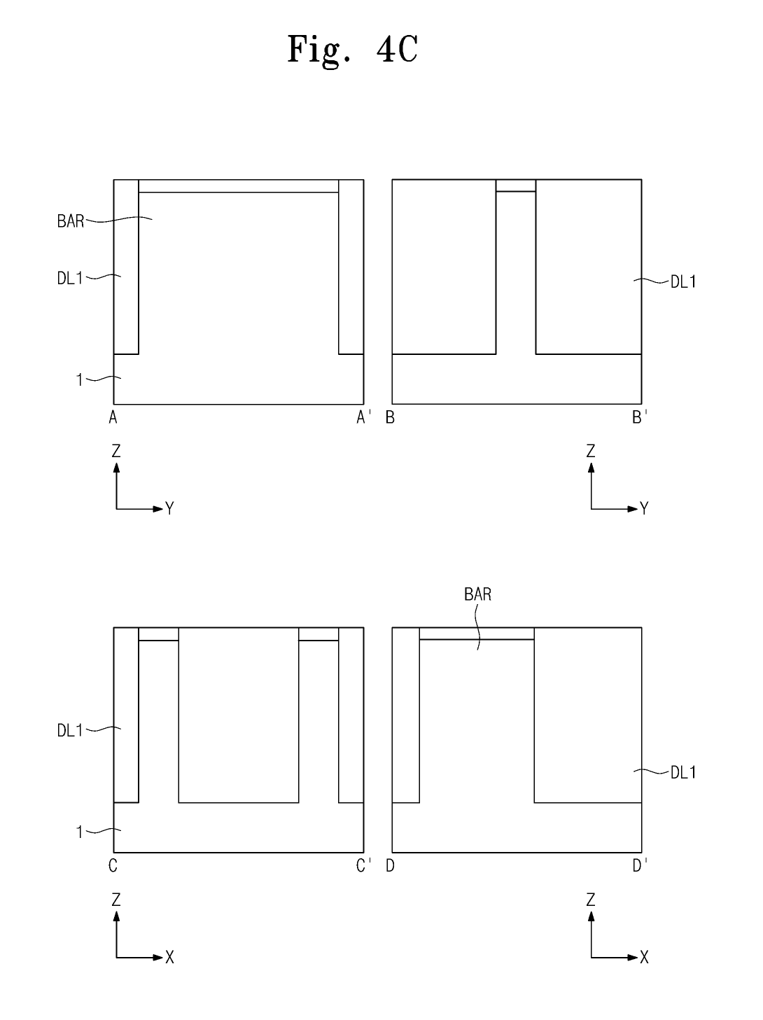

FIGS. 4A through 12A are plan views sequentially illustrating an example process of fabricating the semiconductor device of FIG. 2A. FIGS. 4B, 4C, 5B, 6B, 6C, 7B, 7C, 8B, 8C, 9B, 10B, 11B, and 12B are sectional views taken along lines A-A′, B-B′, C-C′ and D-D′ of FIGS. 4A through 12A, respectively.

Referring to FIGS. 4A and 4B, a first mask pattern HM1 may be formed on a substrate 1. The first mask pattern HM1 may be formed to have a ‘T’-shaped structure in a plan view. The first mask pattern HM1 may be formed of a material having an etch selectivity with respect to the substrate 1. The substrate 1 may be etched using the first mask pattern HM1 as an etch-mask to form a first trench TR1 that may have a first depth D1 and define a lower active portion BAR. In this case, the lower active portion BAR may be a portion of the substrate 1 and the lower active portion BAR may be formed to have a ‘T’-shaped structure in a plan view.

Referring to FIG. 4C, a device isolation layer DL1 may be formed to fill the first trench TR1. The device isolation layer DL1 may include a layer including at least one of, for example, a silicon oxide layer, a silicon nitride layer, or a silicon oxynitride layer.

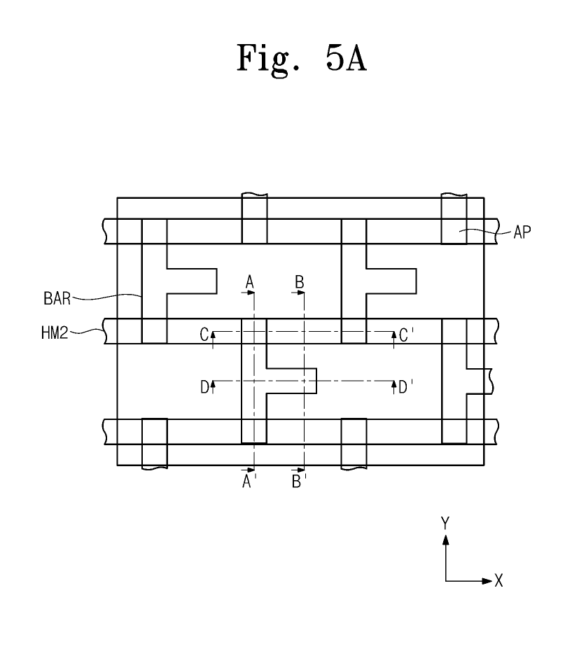

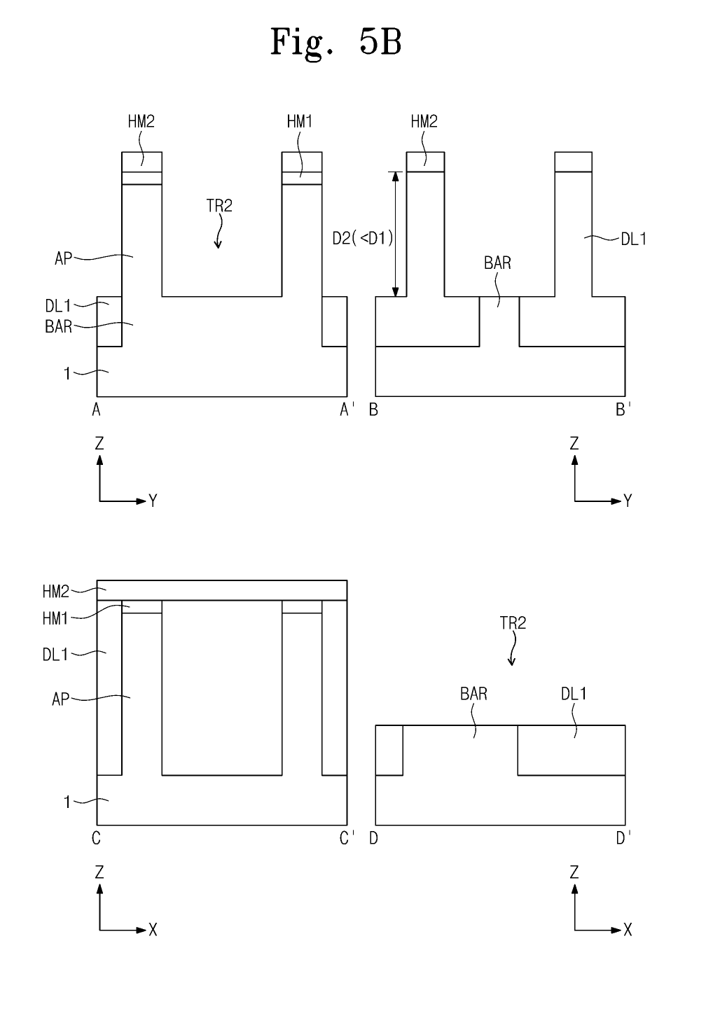

Referring to FIGS. 5A and 5B, a second mask pattern HM2 may be formed on the substrate 1 to cover edge portions of the lower active portion BAR. The second mask pattern HM2 may be shaped like a line or bar extending along a first direction X. The first mask pattern HM1, the device isolation layer DL1 and the lower active portion BAR may be etched using the second mask pattern HM2 as an etch-mask to form a second trench TR2 that may have a second depth D2 and define an active pillar AP. The second depth D2 may be shallower than the first depth D1. the device isolation layer DL1 may be formed to fill spaces between the active pillars AP arranged along the first direction X and expose sidewalls of the active pillars AP facing each other in the second direction Y. In addition, the device isolation layer DL1 may be formed to expose a top surface of the lower active portion BAR.

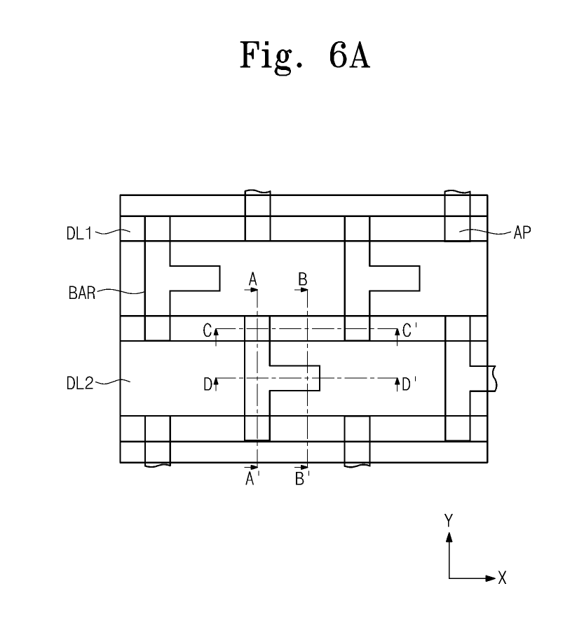

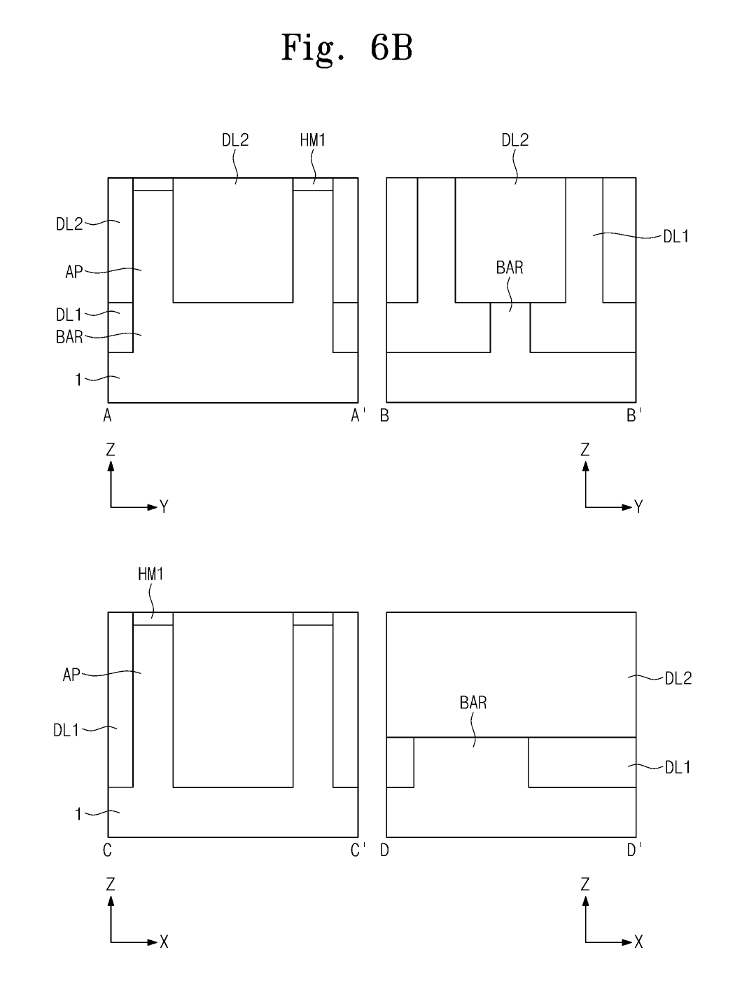

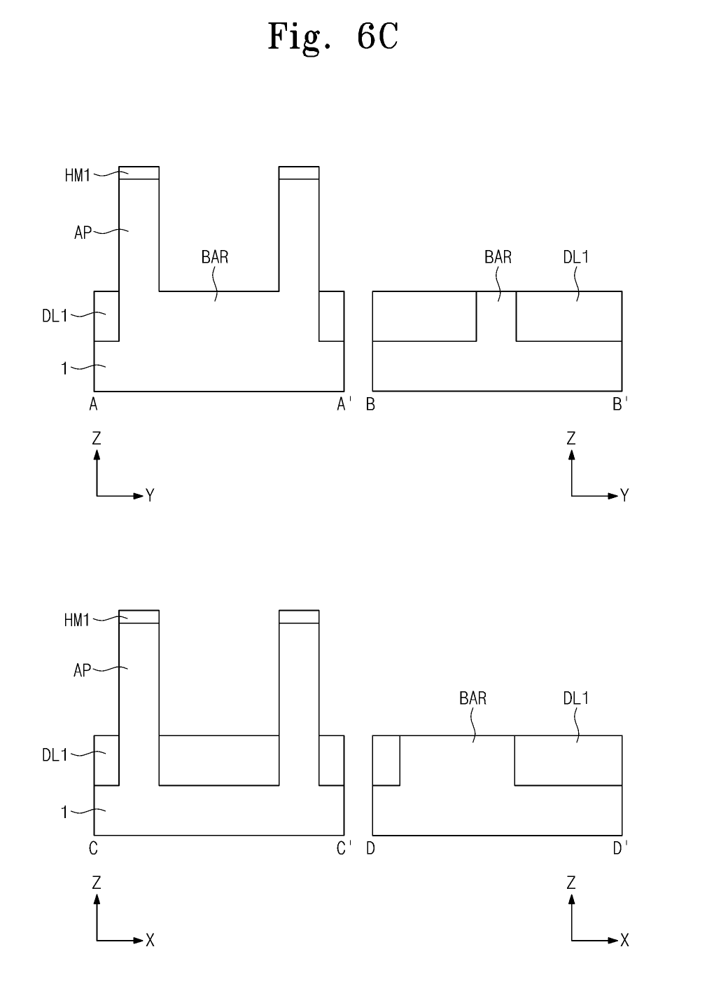

Referring to FIGS. 6A and 6B, the second mask pattern HM2 may be removed, and then, a sacrificial layer DL2 may be formed to fill the second trench TR2. the sacrificial layer DL2 may include the same material as the device isolation layer DL1.

Referring to FIG. 6C, an etching process may be performed to remove the sacrificial layer DL2 and a portion of the device isolation layer DL1. As the result of the etching process, the top surface of the lower active portion BAR may be exposed and the sidewall of the active pillar AP may be wholly exposed. the device isolation layer DL1 may be formed to fill spaces between the lower active portions BAR and have a top surface that is coplanar with that of the lower active portions BAR. the sacrificial layer DL2 may be entirely removed.

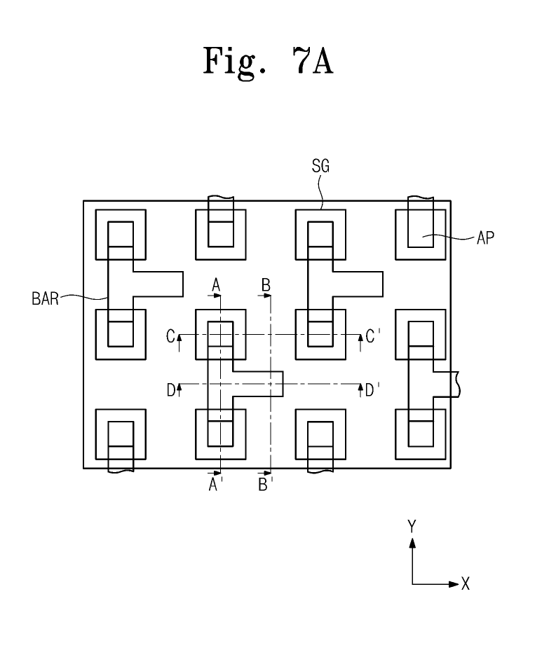

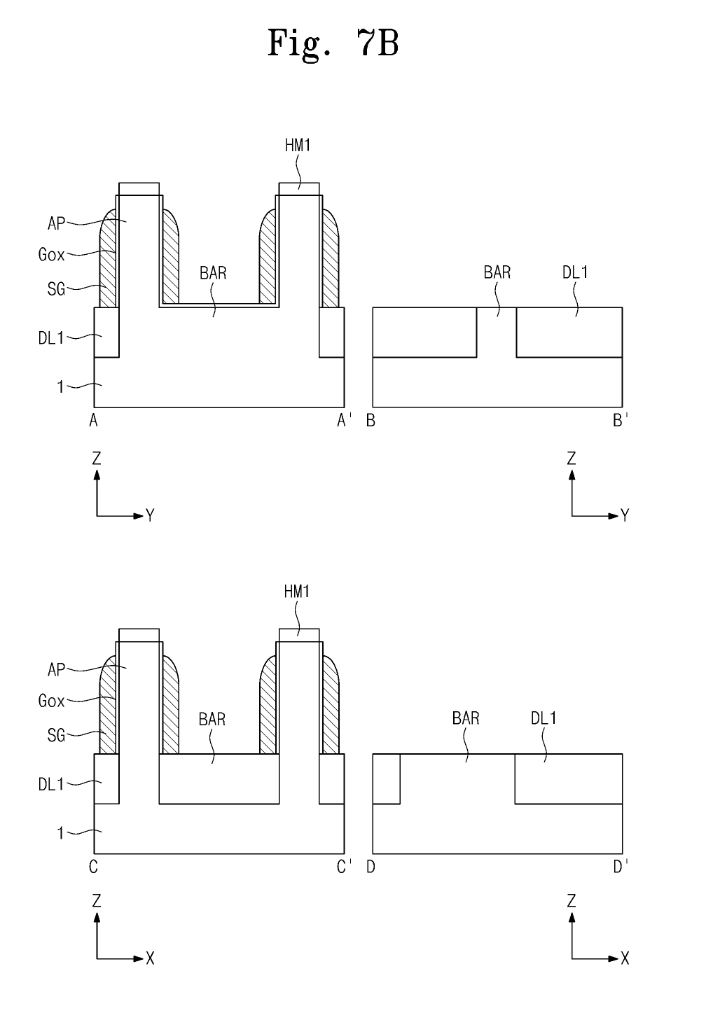

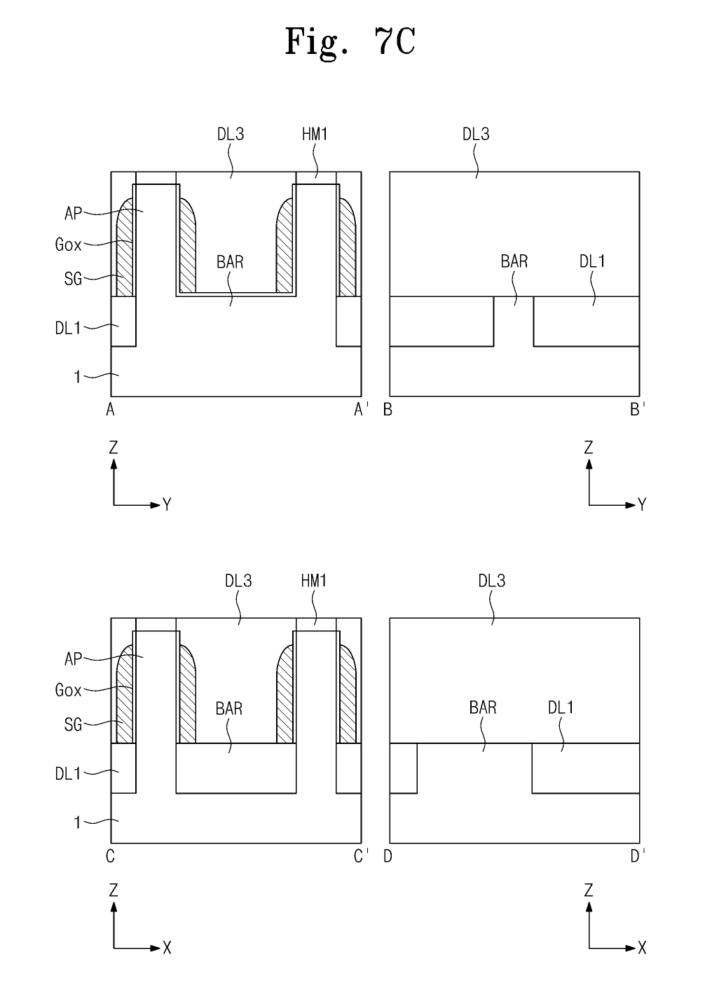

Referring to FIGS. 7A and 7B, a gate insulating layer Gox may be formed on the exposed sidewall of the active pillars AP and the exposed top surface of the lower active portion BAR. The gate insulating layer Gox may be, for example, a silicon oxide layer, which may be formed by a thermal oxidation process. A conductive layer may be formed to conformally cover the sidewall of the active pillars AP provided with gate insulating layer Gox, and be anisotropically etched to form surround gate electrodes SG, each of which surround a sidewall of the active pillar AP. Each of the surround gate electrodes SG may be formed to expose an upper portion of the corresponding one of the active pillars AP.

Referring to FIG. 7C, a first insulating layer DL3 may be formed on the substrate 1 to fill spaces between the surround gate electrodes SG. The first insulating layer DL3 may be etched by a planarization process, and thus, a top surface of the first mask pattern HM1 may be exposed.

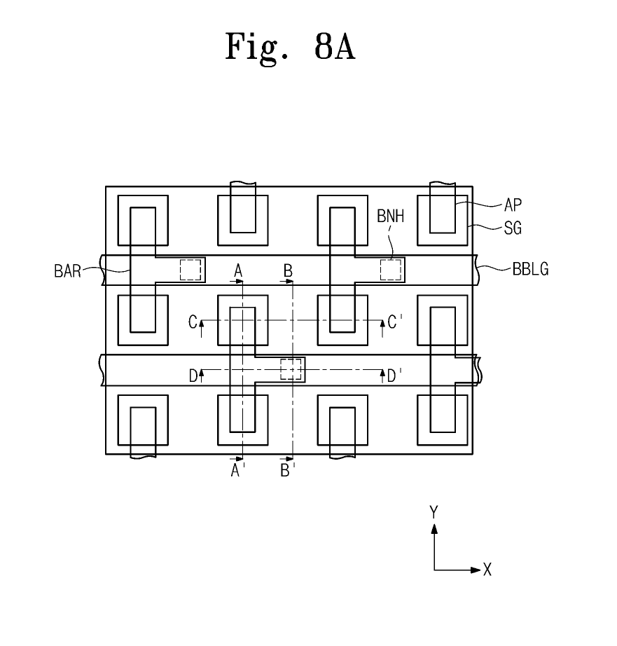

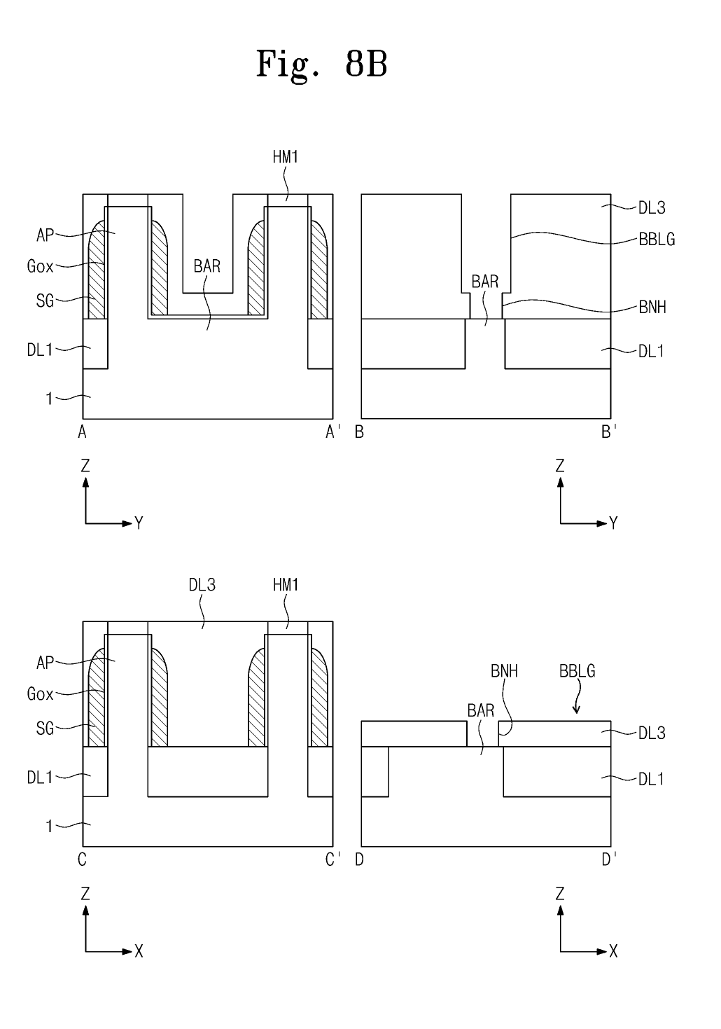

Referring to FIGS. 8A and 8B, the first insulating layer DL3 may be etched to form a bit line groove BBLG between adjacent ones of the surround gate electrodes SG and a bit line node contact hole BNH. The bit line groove BBLG may be formed to extend along the first direction X, and the bit line node contact hole BNH may be locally formed at a bottom surface of the bit line groove BBLG. the bit line groove BBLG and the bit line node contact hole BNH may be formed using a dual damascene process. In addition, the bit line groove BBLG and the bit line node contact hole BNH may be spaced apart, with a uniform spacing, from the surround gate electrodes SG adjacent thereto, for example, by an etching process that may be performed with a spacer in a self-alignment manner. The bit line node contact hole BNH may be formed to expose a top surface of one end portion of the lower active portion BAR.

Referring to FIG. 8C, the first mask pattern HM1 may be removed to expose the top surface of the active pillar AP.

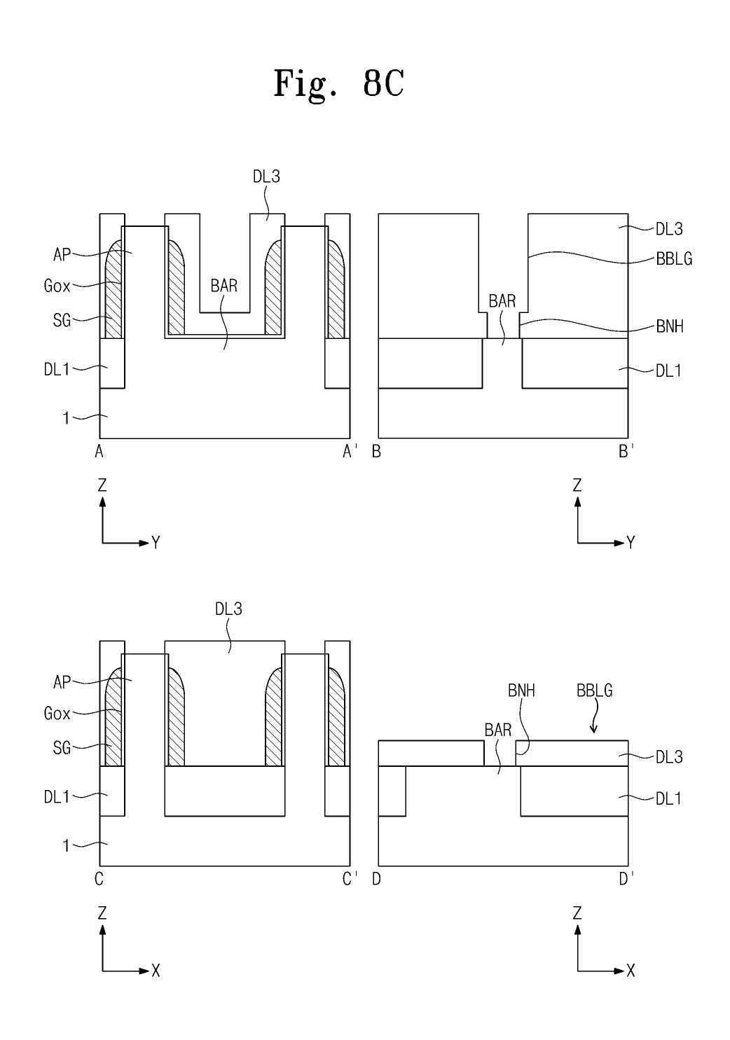

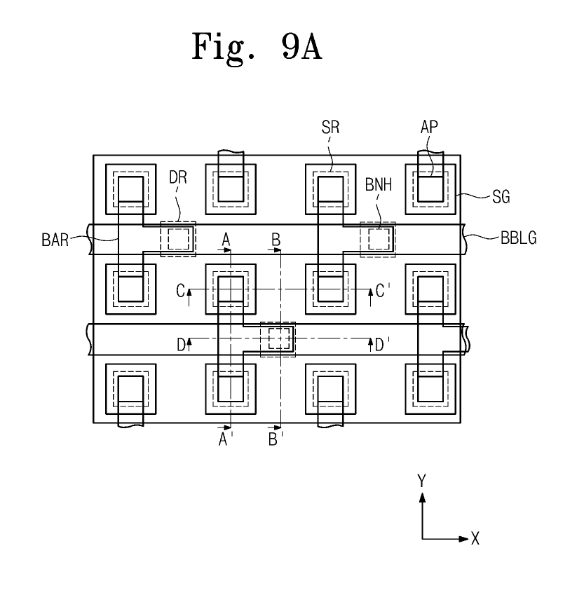

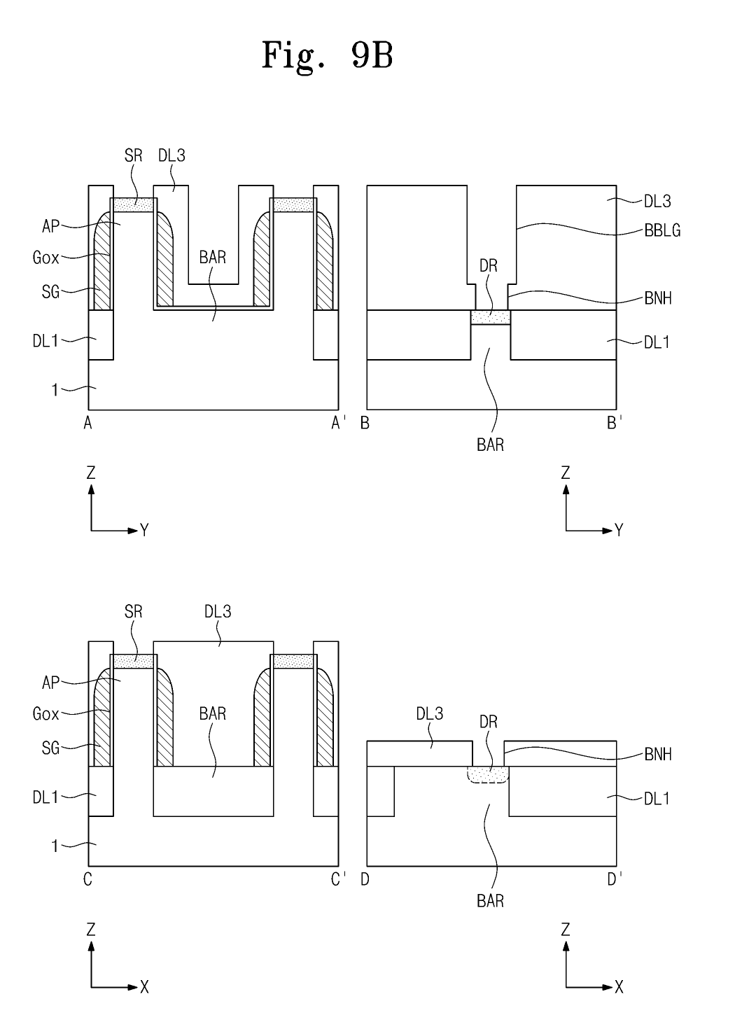

Referring to FIGS. 9A and 9B, an ion implantation process may be performed to form an upper doped region SR and a lower doped region DR. The upper doped region SR may be formed in an upper portion of the active pillar AP, and the lower doped region DR may be formed in the lower active portion BAR that is exposed by the bit line node contact hole BNH. the ion implantation process may be performed in a tilting angle of about 0° and with n-type impurities.

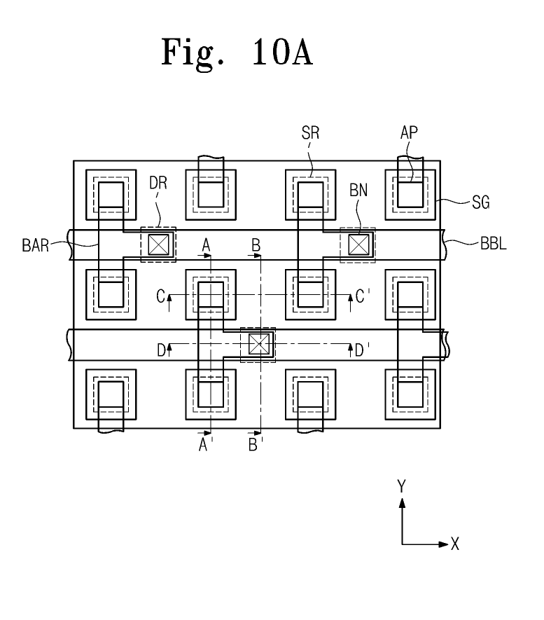

Referring to FIGS. 10A and 10B, a conductive layer may be formed to fill the bit line node contact hole BNH and the bit line groove BBLG. Thereafter, the conductive layer may be etched to expose an upper inner wall of the bit line groove BBLG. As a result, a bit line node contact BN and a buried bit line BBL may be formed in the bit line node contact hole BNH and the bit line groove BBLG, respectively. The conductive layer may remain on the active pillar AP during the formation of the bit line node contact BN and buried bit line BBL. Alternatively, the top surface of the active pillar AP may be covered with a protection layer. Next, a second insulating layer DL4 may be formed to fill the bit line groove BBLG. the second insulating layer DL4 may cover the top surface of the active pillar AP.

As shown in FIGS. 9A and 9B, the lower doped region DR may be formed using the process of forming the upper doped region SR; that is, the lower and upper doped regions DR and SR may be simultaneously formed. Alternatively, the lower doped region DR may be formed after the formation of the buried bit line BBL. For example, the buried bit line BBL may be formed of a doped polysilicon layer, and in this case, the lower doped region DR may be formed by diffusing impurities of the buried bit line BBL into the lower active portion BAR.

Referring to FIGS. 11A and 11B, the first insulating layer DL3 may be partially removed between the adjacent ones of the surround gate electrodes SG to form a contact gate electrode hole partially exposing sidewalls of the surround gate electrodes SG. Thereafter, a contact gate electrode CG may be formed by filling the contact gate electrode hole with a conductive material. The contact gate electrode CG may be formed to be in contact with the facing sidewalls of two adjacent surround gate electrodes SG.

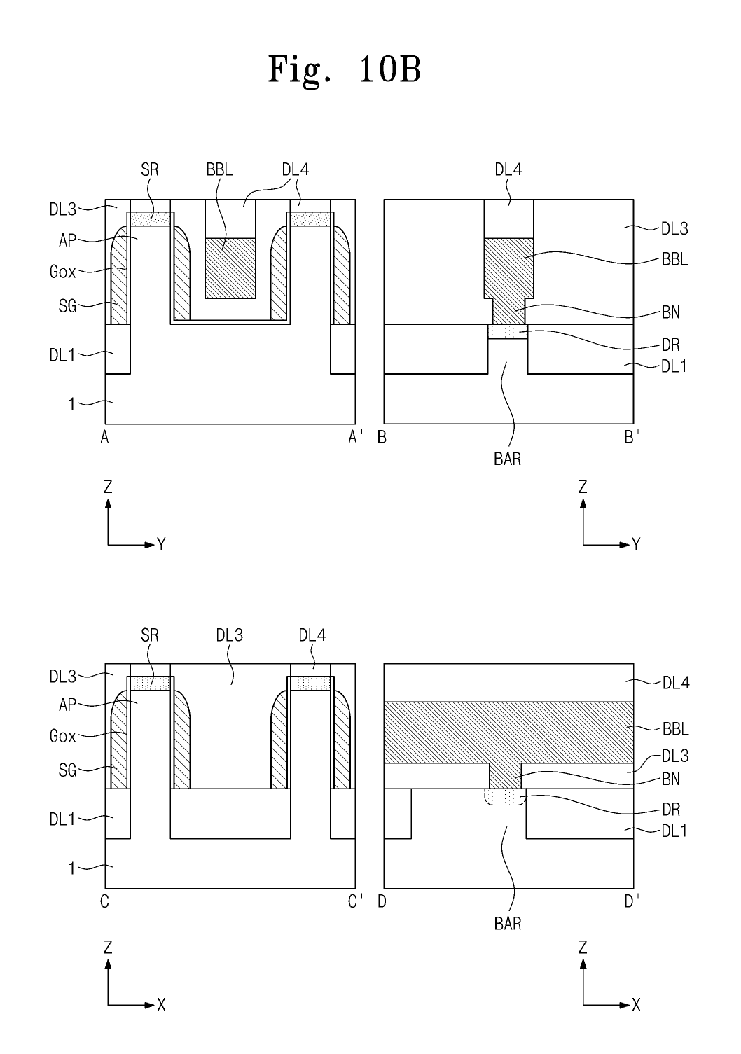

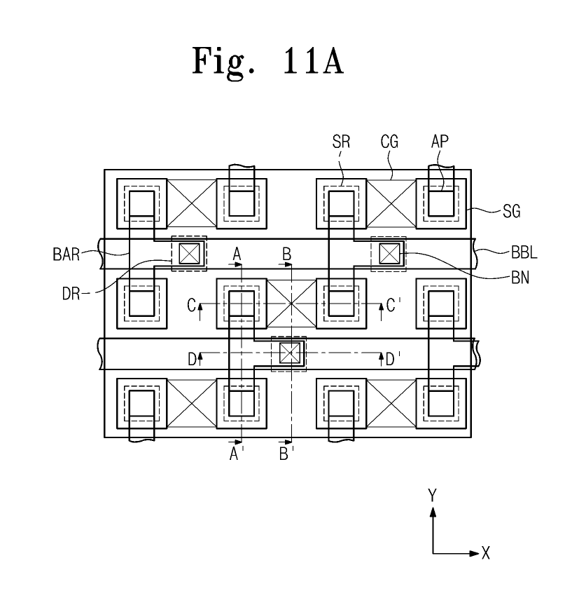

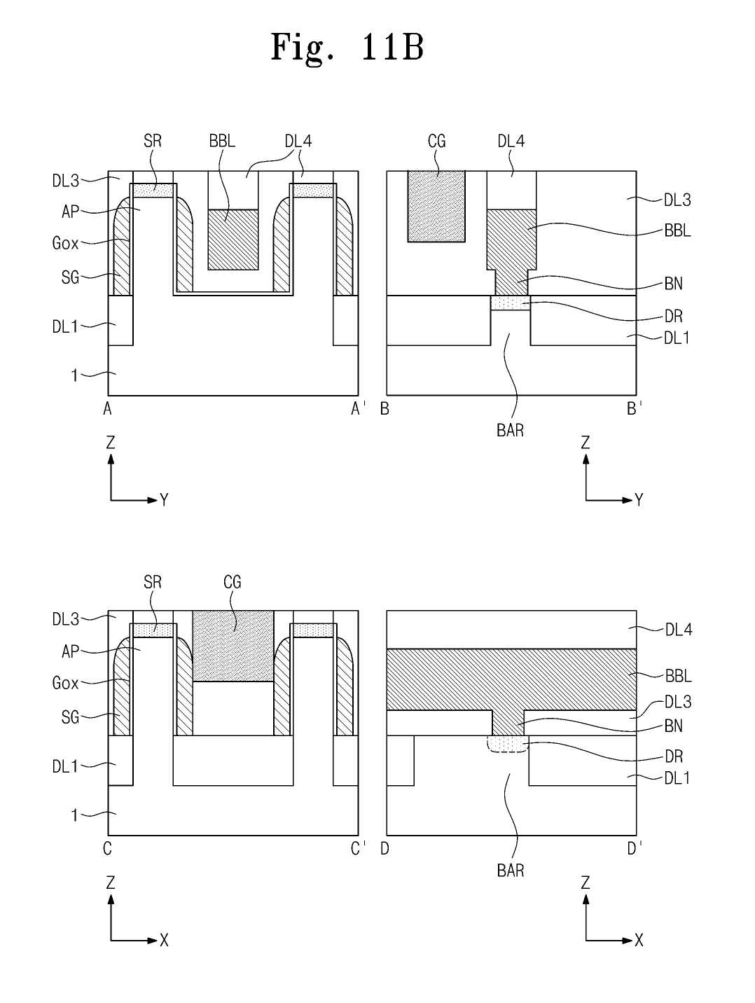

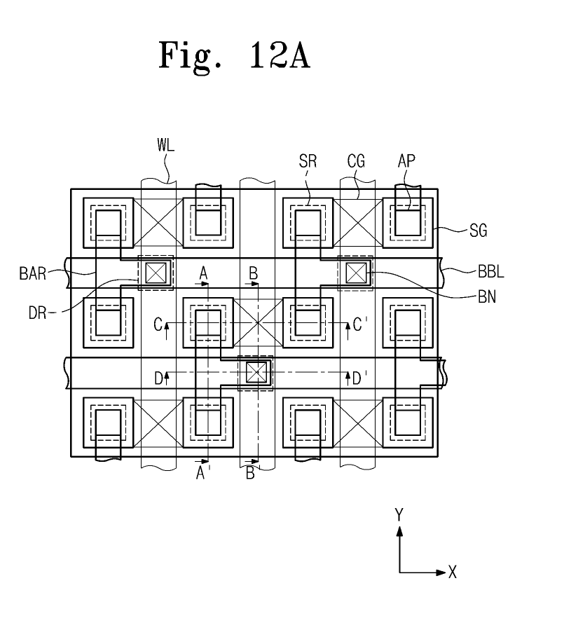

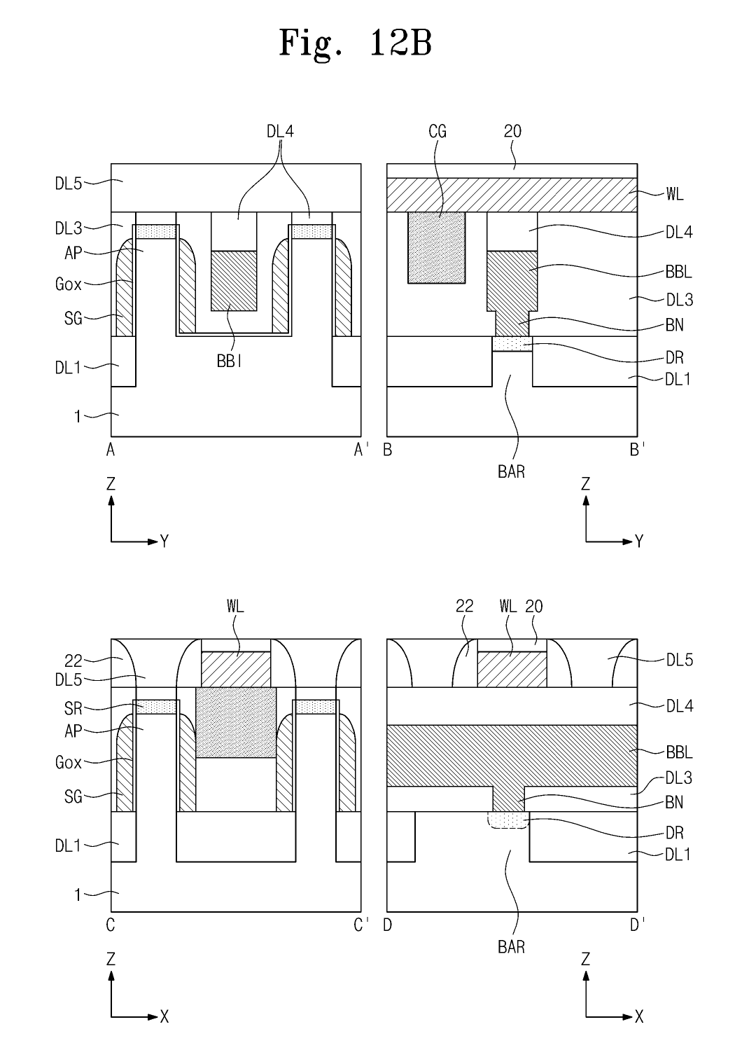

Referring to FIGS. 12A and 12B, a conductive layer and a capping layer 20 may be stacked on the first insulating layer DL3 and be patterned to form a word line WL extending along the second direction Y. A spacer 22 may be formed to cover sidewalls of the word line WL. A third insulating layer DL5 may be formed to fill spaces between the word lines WL adjacent to each other. The word line WL may be formed to be in contact with the contact gate electrode CG.

Referring back to FIGS. 2A, 2B and 2C, the third insulating layer DL5 and the second insulating layer DL4 may be partially removed to form a storage node pad hole, and then, a storage node pad SN may be formed by filling the storage node pad hole with a conductive layer. Thereafter, a data storing element DS may be formed on the storage node pad SN.

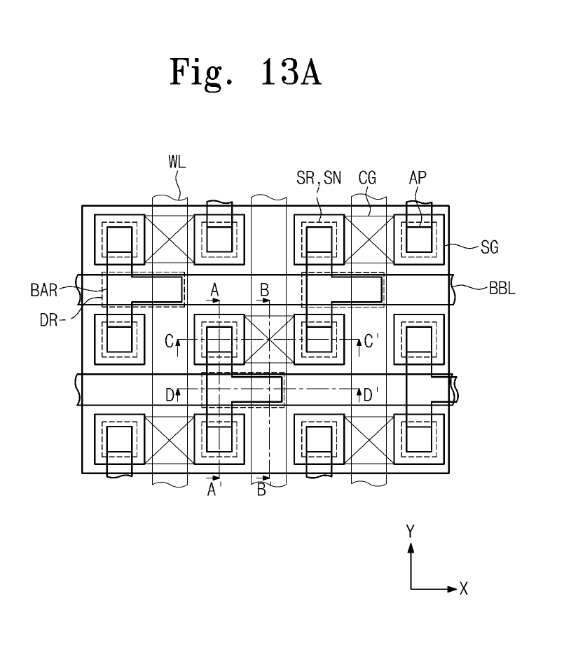

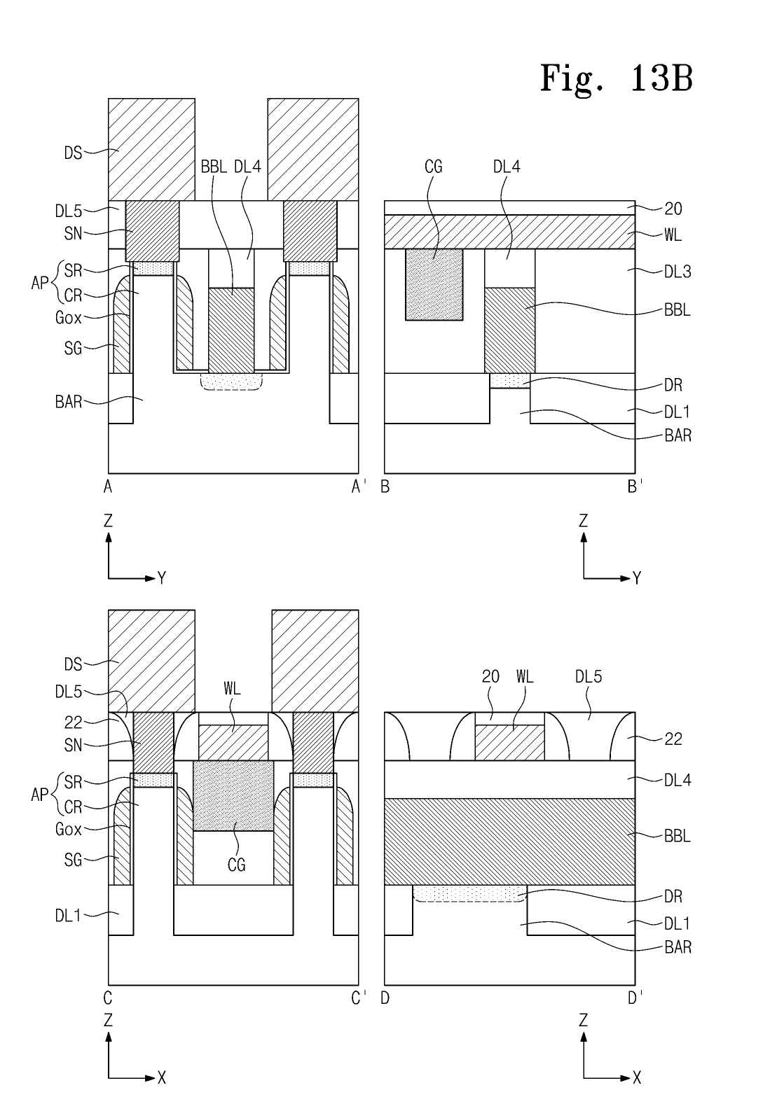

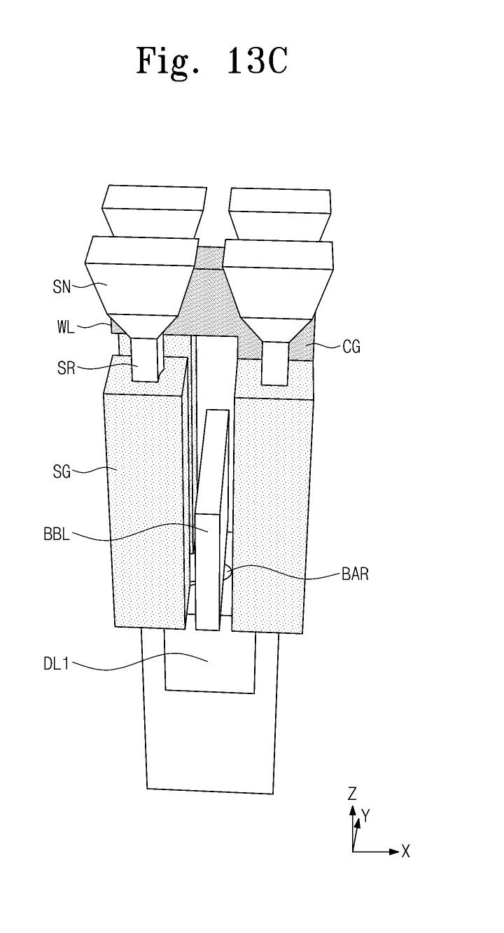

FIG. 13A is a plan view of a semiconductor device according to example embodiments of inventive concepts, and FIG. 13B shows sectional views taken along lines A-A′, B-B′, C-C′ and D-D′ of FIG. 13A. In addition, FIG. 13C is a perspective view of the semiconductor device according to example embodiments of inventive concepts.

Referring to FIGS. 13A, 13B and 13C, in a semiconductor device according to example embodiments of inventive concepts, the buried bit line BBL may be in direct contact with the lower active portion BAR, without the bit line node contact BN. In addition, the lower doped region DR may be formed in the lower active portion BAR below the buried bit line BBL. An area of the lower doped region DR may be increased, compared with that of the semiconductor device described with reference to FIGS. 2A through 12A. As a result, a contact area between the buried bit line BBL and the lower doped region DR may be increased, compared with that of the semiconductor device described with reference to FIGS. 2A through 12A, and thus, it is possible to reduce a contact resistance between the buried bit line BBL and the lower doped region DR.

The formation of the bit line node contact hole BNH described with reference to FIGS. 8A and 8B may be omitted, and the fabrication of the semiconductor device may include forming the bit line groove BBLG to expose the top surface of the lower active portion BAR, before the formation of the lower doped region DR and the buried bit line BBL.

Except for the afore-described technical modifications, the semiconductor device of the FIGS. 13A to 13C may be fabricated using the method of FIGS. 4A through 12B, and therefore, have the same or similar structure as that of the semiconductor device illustrated in FIGS. 2A to 2C.

FIG. 14A is a plan view of a semiconductor device according to example embodiments of inventive concepts, and FIG. 14B shows sectional views taken along lines A-A′, B-B′, C-C′ and D-D′ of FIG. 14A.

Referring to FIGS. 14A and 14B, the lower active portion BAR may be formed to have a cross shape in a plan view. In addition, two bit line node contacts BN may be formed on two end portions of one lower active portion BAR, respectively. Two lower doped regions DR may be formed in one lower active portion BAR. Accordingly, a total contact area between the buried bit line BBL and the lower doped regions DR may be increased, and thus, it is possible to reduce a contact resistance between the buried bit line BBL and the lower doped region DR.

Except for the afore-described technical modifications, the semiconductor device of the FIGS. 14A to 14B may be fabricated using the method of FIGS. 4A to 12B, and therefore, have the same or similar structure as that of semiconductor device shown in FIGS. 2A to 2C.

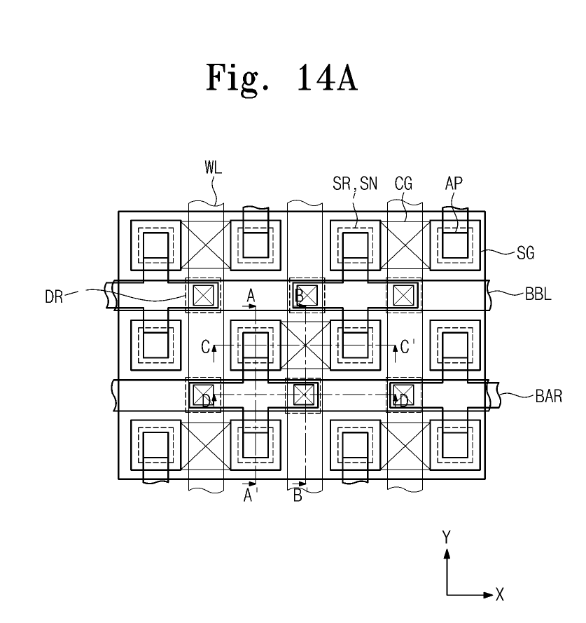

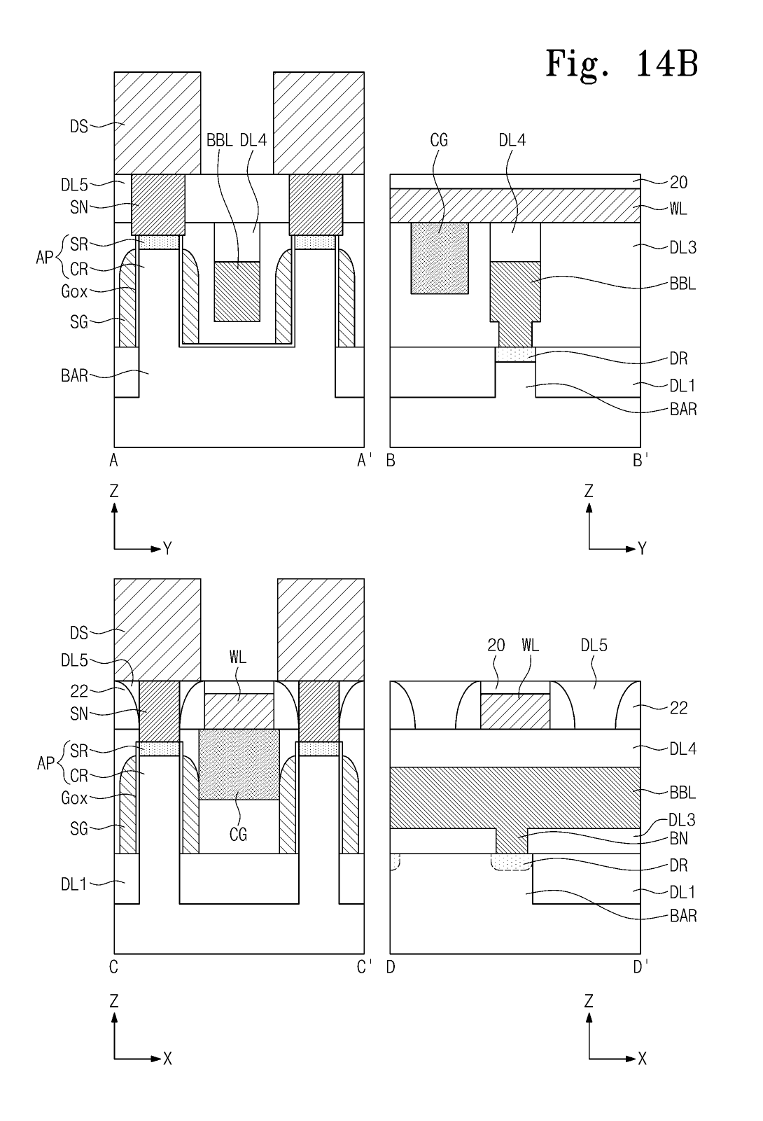

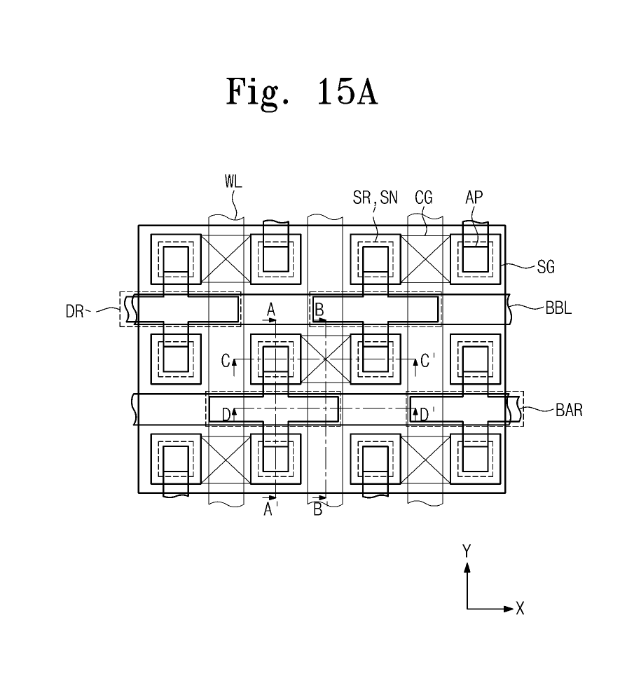

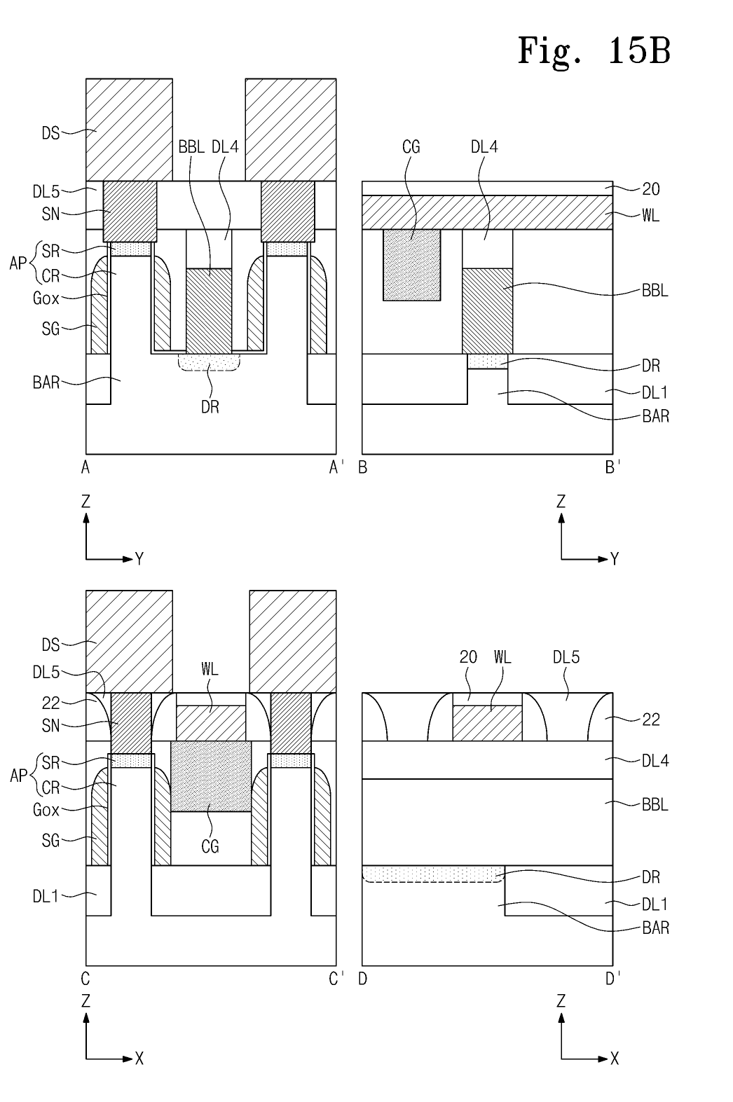

FIG. 15A is a plan view of a semiconductor device according to example embodiments of inventive concepts, and FIG. 15B shows sectional views taken along lines A-A′, B-B′, C-C′ and D-D′ of FIG. 15A.

Referring to FIGS. 15A and 15B, the lower active portion BAR may be formed to have a cross shape in a plan view. The buried bit line BBL may be in direct contact with the lower active portion BAR, without the bit line node contact BN. As a result, a total contact area between the buried bit line BBL and the lower doped regions DR may be increased, compared with that of semiconductor device shown in FIGS. 2A to 2C, and thus, it is possible to reduce a contact resistance between the buried bit line BBL and the lower doped region DR.

Except for the afore-described technical modifications, the semiconductor device of the FIGS. 15A to 15B embodiment may be fabricated using the method of FIGS. 4A through 12B, and therefore, have the same or similar structure as that of the semiconductor device illustrated in FIGS. 2A to 2C.

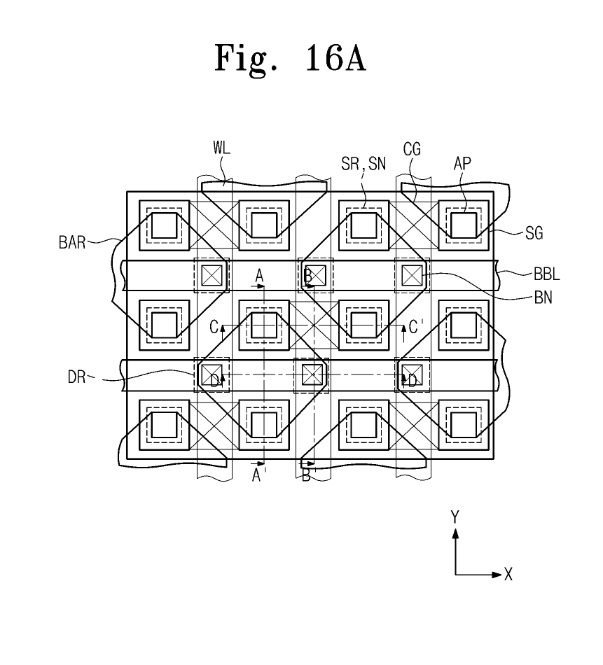

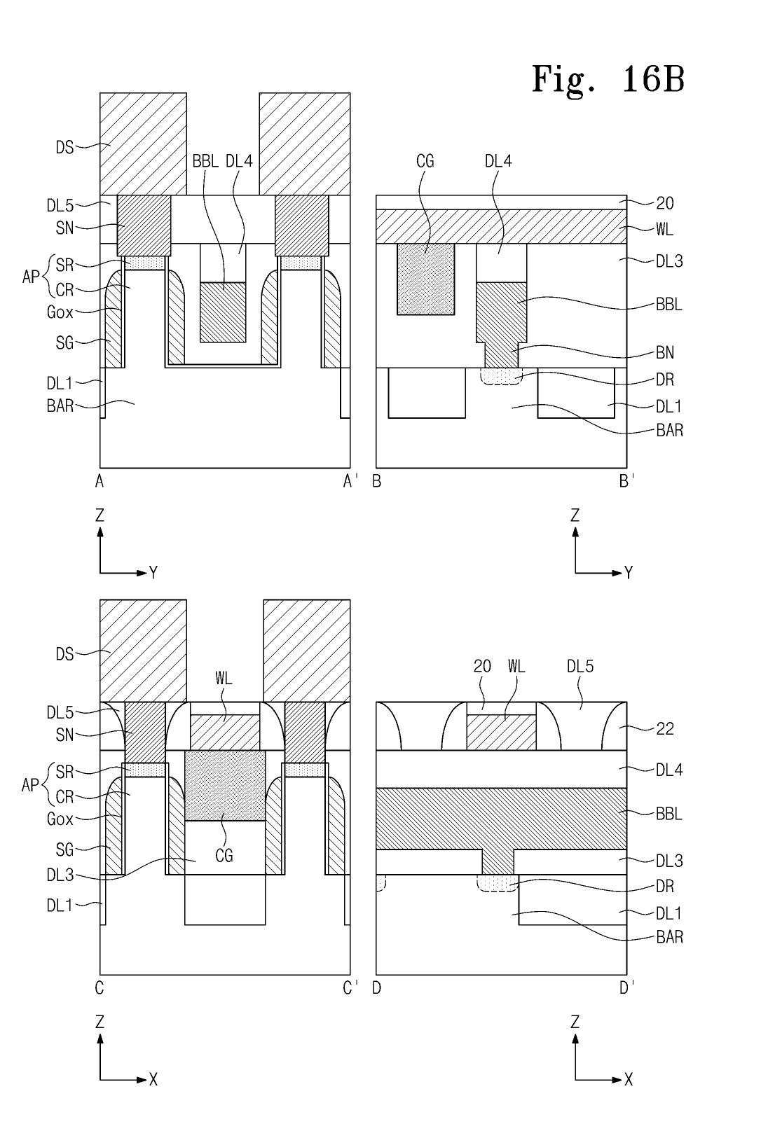

FIG. 16A is a plan view of a semiconductor device according to example embodiments of inventive concepts, and FIG. 16B shows sectional views taken along lines A-A′, B-B′, C-C′ and D-D′ of FIG. 16A.

Referring to FIGS. 16A and 16B, the lower active portion BAR may be formed to have a diamond shape in a plan view. In addition, two bit line node contacts BN may be formed on two end portions of one lower active portion BAR, respectively. Two lower doped regions DR may be formed in one lower active portion BAR. Accordingly, a total contact area between the buried bit line BBL and the lower doped regions DR may be increased, compared with that of semiconductor device shown in FIGS. 2A to 2C, and thus, it is possible to reduce a contact resistance between the buried bit line BBL and the lower doped region DR.

Except for the afore-described technical modifications, the semiconductor device shown in FIGS. 16A to 16B may be fabricated using the method shown in FIGS. 4A to 12B, and therefore, have the same or similar structure as that of the device shown in FIGS. 2A to 2C.

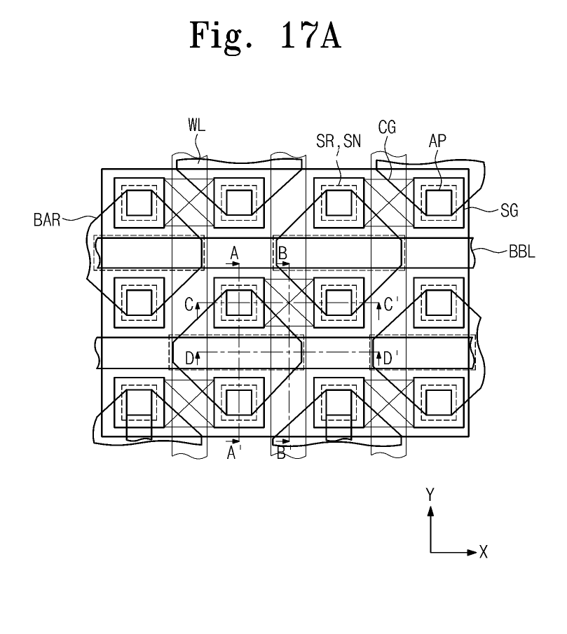

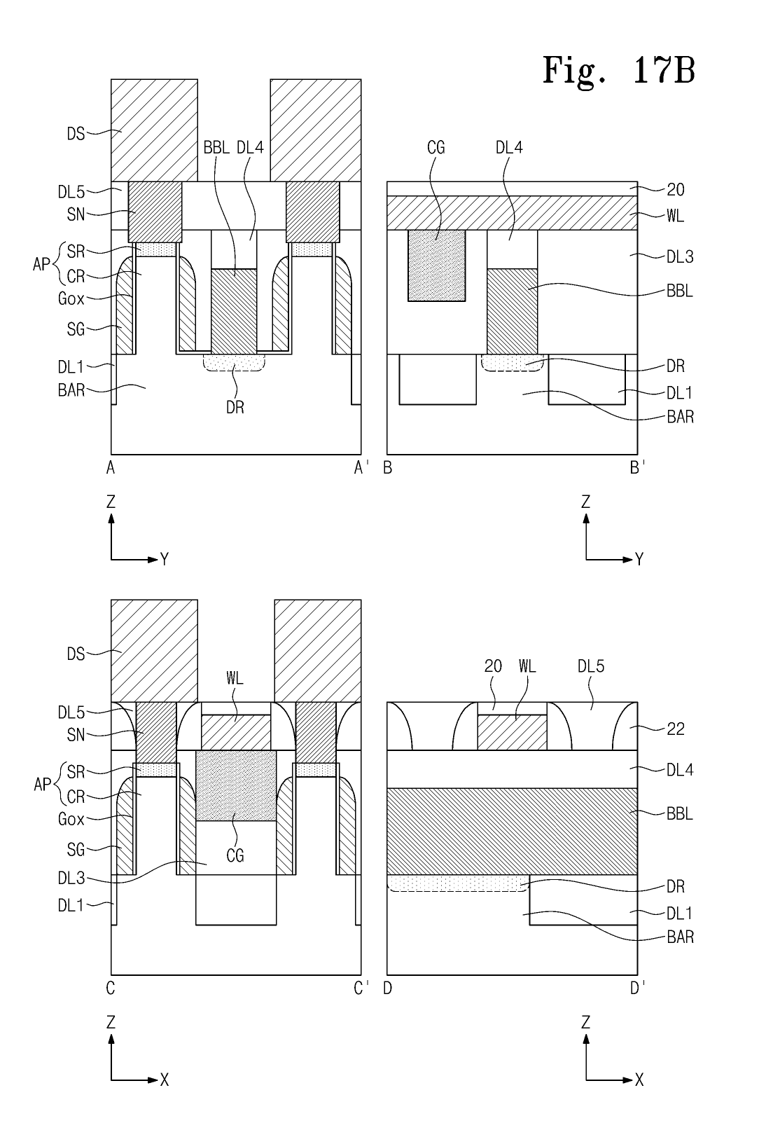

FIG. 17A is a plan view of a semiconductor device according to example embodiments of inventive concepts, and FIG. 17B shows sectional views taken along lines A-A′, B-B′, C-C′ and D-D′ of FIG. 17A.

Referring to FIGS. 17A and 17B, the lower active portion BAR may be formed to have a diamond shape in a plan view. The buried bit line BBL may be in direct contact with the lower active portion BAR, without the bit line node contact BN. As a result, a total contact area between the buried bit line BBL and the lower doped regions DR may be increased, compared with that of semiconductor device shown in FIGS. 2A to 2C, and thus, it is possible to reduce a contact resistance between the buried bit line BBL and the lower doped region DR.

Except for the afore-described technical modifications, the semiconductor device of FIGS. 17A and 17B may be fabricated using the method of FIGS. 4A through 12B, and therefore, have the same or similar structure as that of the semiconductor device illustrated in FIGS. 2A to 2C.

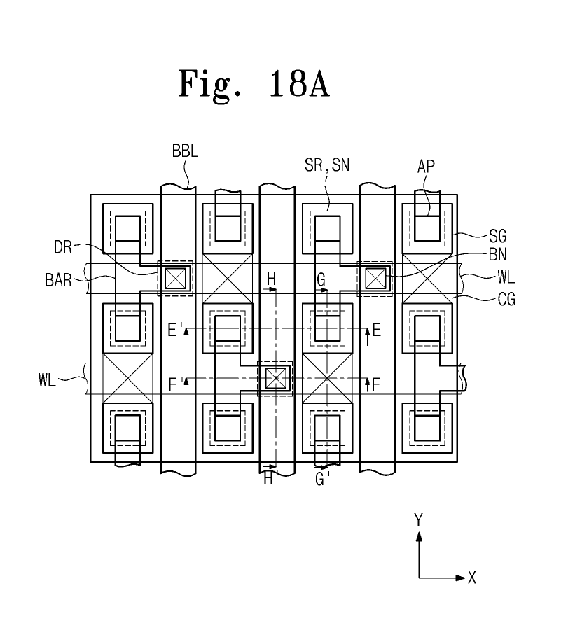

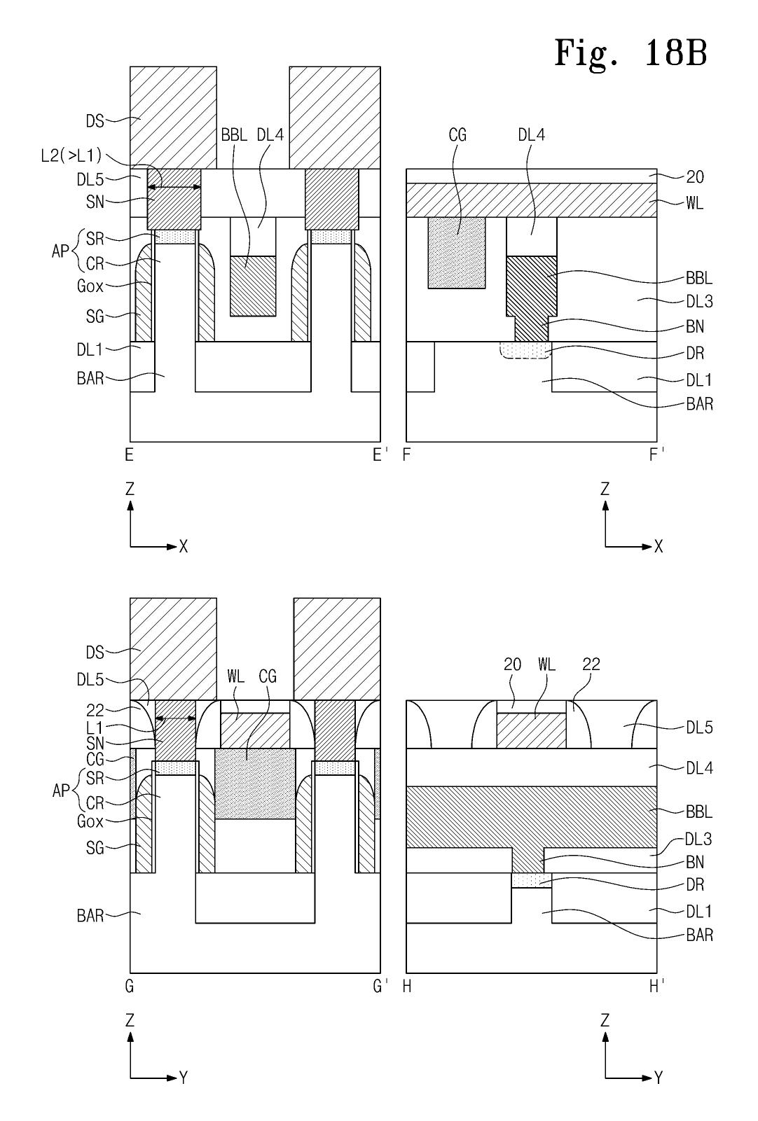

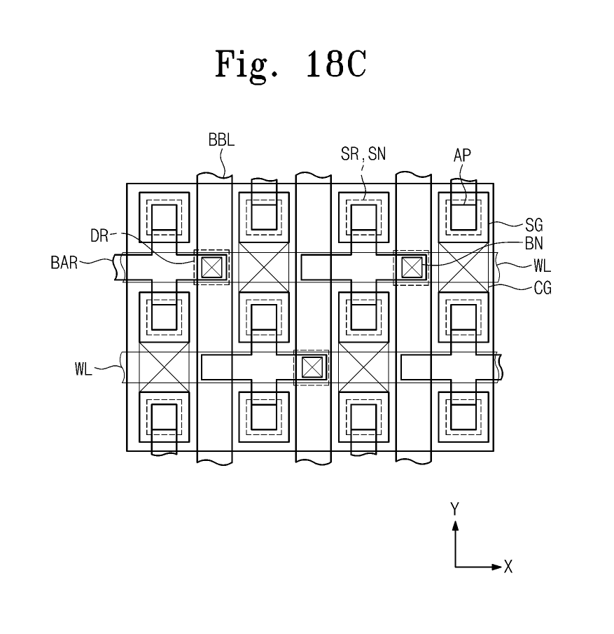

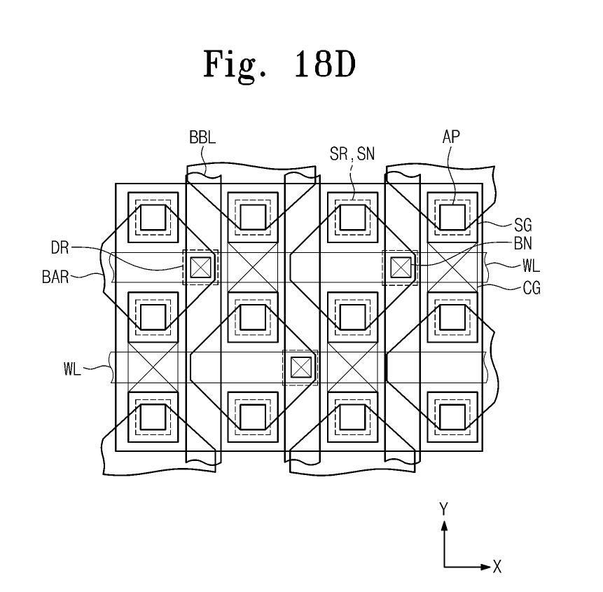

FIG. 18A is a plan view of a semiconductor device according to example embodiments of inventive concepts, and FIG. 18B shows sectional views taken along lines E-E′, F-F′, G-G′ and H-H′ of FIG. 18A.

Referring to FIGS. 18A and 18B, the buried bit line BBL may extend along the second direction Y, and the word line WL may extend along the first direction X. The buried bit line BBL may overlap an end-portion of the ‘T’-shaped lower active portion BAR, and thus, an overlapping area between the buried bit line BBL and the lower active portion BAR may be reduced, compared with that of semiconductor device shown in FIGS. 2A to 2C. The bit line node contact BN may be interposed between the buried bit line BBL and the lower active portion BAR. The storage node pad SN may have a first side parallel to the buried bit line BBL and a second side parallel to the word line WL, and a width L2 of the second side may be greater than a width L1 of the first side. Furthermore, the width L2 of the second side may be greater than a width of the active pillar AP. Positions of the contact gate electrodes CG may be changed to correspond with alteration in dispositions of the buried bit line BBL and the word line WL, as shown in FIG. 18A. Alternatively, the lower active portion BAR may be formed to have a cross shape in a plan view as shown in FIG. 18C or a diamond shape in a plan view as illustrated in FIG. 18D.

Except for the afore-described technical modifications, the semiconductor device of the of FIGS. 18A to 18B may be fabricated using the method of FIGS. 4A to 12C, and therefore, have the same or similar structure as that of semiconductor device shown in FIGS. 2A to 2C.

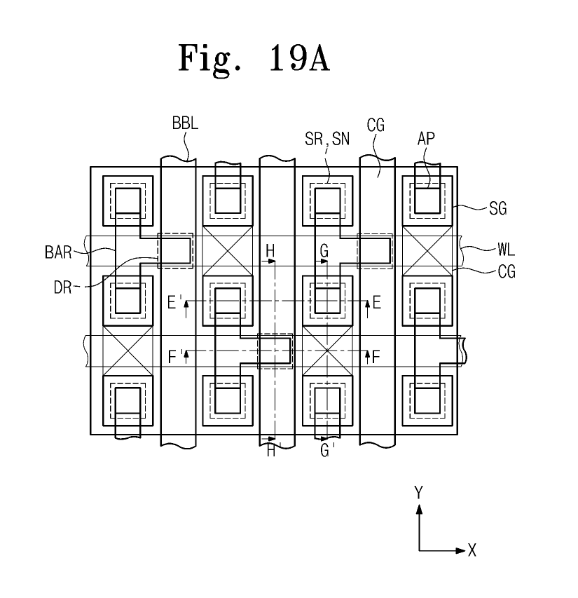

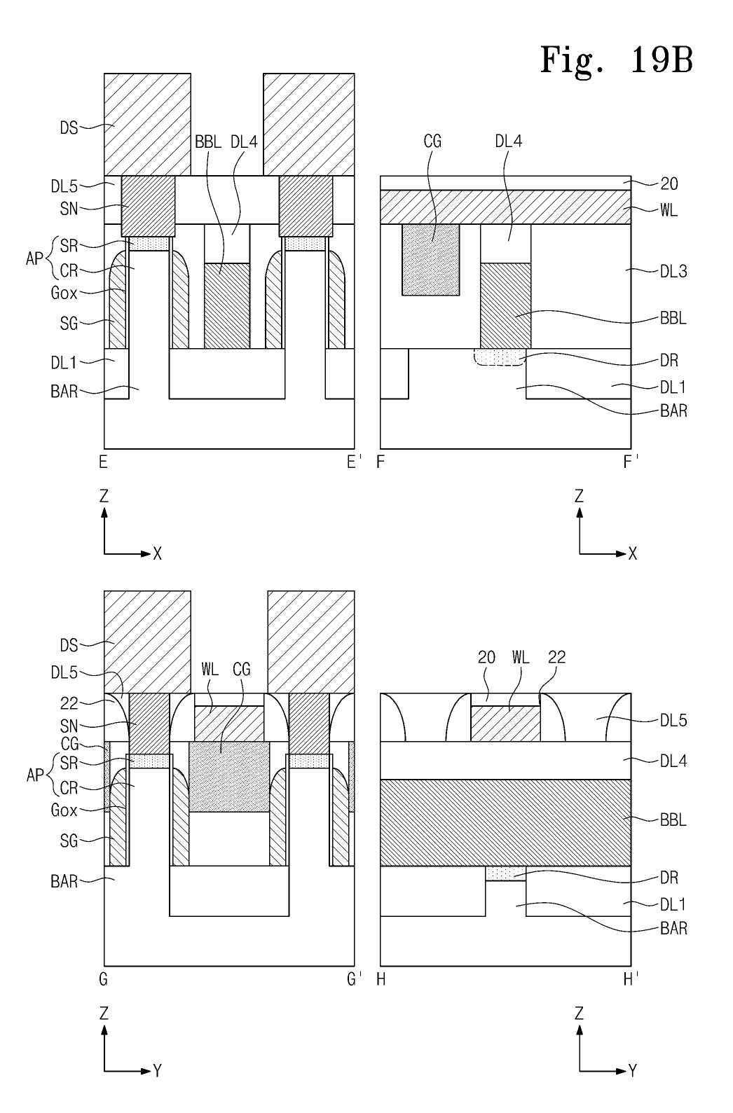

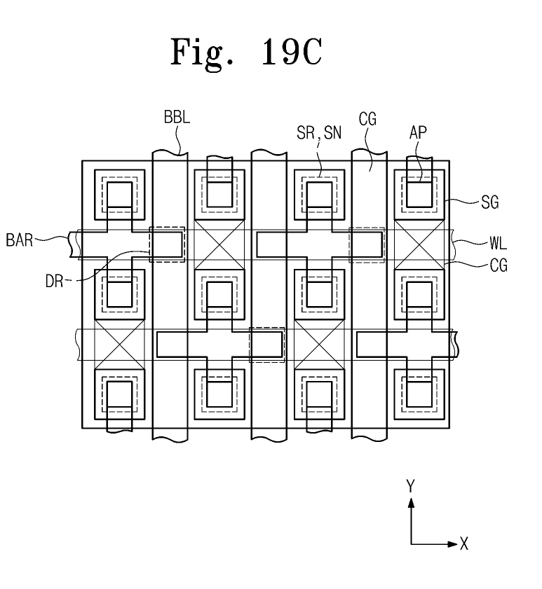

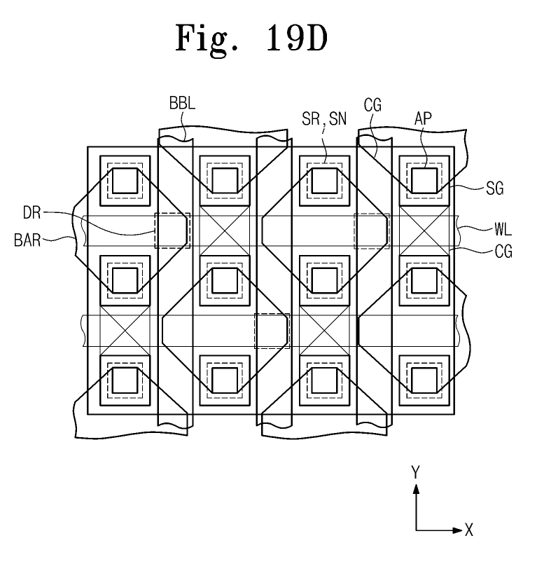

FIG. 19A is a plan view of a semiconductor device according to example embodiments of inventive concepts, and FIG. 19B shows sectional views taken along lines E-E′, F-F′, G-G′ and H-H′ of FIG. 19A.

Referring to FIGS. 19A and 19B, the buried bit line BBL may extend along the second direction Y, and the word line WL may extend along the first direction X. The buried bit line BBL may overlap an end-portion of the ‘T’-shaped lower active portion BAR, and thus, an overlapping area between the buried bit line BBL and the lower active portion BAR may be reduced, compared with that of semiconductor device shown in FIGS. 2A to 2C. The buried bit line BBL may be in direct contact with the lower active portion BAR, without the bit line node contact BN. Alternatively, the lower active portion BAR may be formed to have a cross shape in a plan view as shown in FIG. 19C or a diamond shape in a plan view as illustrated in FIG. 19D.

Except for the afore-described technical modifications, the semiconductor device of the FIGS. 19A to 19B may be fabricated using the method of FIGS. 4A through 12B, and therefore, have the same or similar structure as that of the semiconductor device illustrated in FIGS. 2A to 2C.

Semiconductor memory devices according to example embodiments of inventive concepts may be encapsulated using various and diverse packaging techniques. For example, the semiconductor memory devices may be encapsulated using any one of a package on package (POP) technique, a ball grid arrays (BGAs) technique, a chip scale packages (CSPs) technique, a plastic leaded chip carrier (PLCC) technique, a plastic dual in-line package (PDIP) technique, a die in waffle pack technique, a die in wafer form technique, a chip on board (COB) technique, a ceramic dual in-line package (CERDIP) technique, a plastic quad flat package (PQFP) technique, a thin quad flat package (TQFP) technique, a small outline package (SOIC) technique, a shrink small outline package (SSOP) technique, a thin small outline package (TSOP) technique, a thin quad flat package (TQFP) technique, a system in package (SIP) technique, a multi-chip package (MCP) technique, a wafer-level fabricated package (WFP) technique and a wafer-level processed stack package (WSP) technique.

The package in which a semiconductor memory device according to example embodiments of inventive concepts is mounted may further include at least one semiconductor device (e.g., a controller and/or a logic device) that controls the semiconductor memory device.

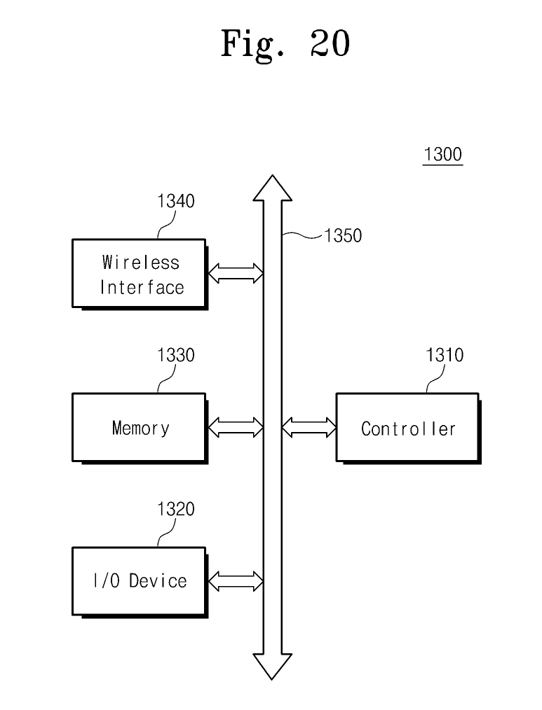

FIG. 20 is a block diagram schematically illustrating electronic devices including a semiconductor device according to example embodiments of inventive concepts.

Referring to FIG. 20, an electronic device 1300 including a semiconductor device according to example embodiments of inventive concepts may be used in one of a personal digital assistant (PDA), a laptop computer, a mobile computer, a web tablet, a wireless phone, a cell phone, a digital music player, a wire or wireless electronic device, or a complex electronic device including at least two ones thereof. The electronic device 1300 may include a controller 1310, an input/output device 1320 such as a keypad, a keyboard, a display, a memory 1330, and a wireless interface 1340 that are combined to each other through a bus 1350. The controller 1310 may include, for example, at least one microprocessor, a digital signal process, a microcontroller or the like. The memory 1330 may be configured to store a command code to be used by the controller 1310 or a user data. The memory 1330 may include a semiconductor device including a vertical channel transistor according to example embodiments of inventive concepts. The electronic device 1300 may use a wireless interface 1340 configured to transmit data to or receive data from a wireless communication network using a RF signal. The wireless interface 1340 may include, for example, an antenna, a wireless transceiver and so on. The electronic system 1300 may be used in a communication interface protocol of a communication system such as CDMA, GSM, NADC, E-TDMA, WCDMA, CDMA2000, Wi-Fi, Muni Wi-Fi, Bluetooth, DECT, Wireless USB, Flash-OFDM, IEEE 802.20, GPRS, iBurst, WiBro, WiMAX, WiMAX-Advanced, UMTS-TDD, HSPA, EVDO, LTE-Advanced, MMDS, and so forth.

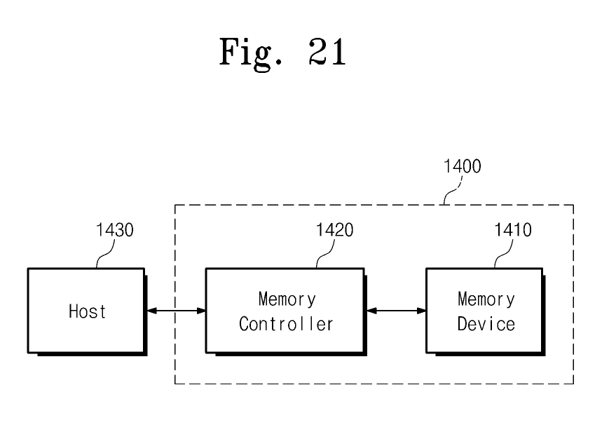

FIG. 21 is a block diagram schematically illustrating memory systems including a semiconductor device according to example embodiments of inventive concepts.

Referring to FIG. 21, a memory system including a semiconductor device according to example embodiments of inventive concepts will be described. The memory system 1400 may include a memory device 1410 for storing huge amounts of data and a memory controller 1420. The memory controller 1420 controls the memory device 1410 so as to read data stored in the memory device 1410 or to write data into the memory device 1410 in response to a read/write request of a host 1430. The memory controller 1420 may include an address mapping table for mapping an address provided from the host 1430 (e.g., a mobile device or a computer system) into a physical address of the memory device 1410. The memory device 1410 may be a semiconductor device including a vertical channel transistor according to example embodiments of inventive concepts.

According to example embodiments of inventive concepts, the semiconductor device may include a buried bit line disposed between surround gate electrodes adjacent to each other to surround an active pillar. As a result, the buried bit line may serve as a shielding layer capable of reducing a coupling noise between the adjacent surround gate electrodes. Furthermore, the surround gate electrode may be formed to surround the active pillar and can serve as a shielding layer preventing a coupling noise from occurring between the buried bit line and a channel region of the active pillar adjacent thereto.

In addition, since the active pillar is surrounded by the surround gate electrode, the channel region can be widened. This enables to increase an on-current of the transistor and improve a sub-threshold property of the transistor. The lower doped region does not overlap the active pillar in terms of vertical level, and thus, the channel region can be electrically connected to a substrate and thus be limited (and/or prevented) from being electrically floated.

While some example embodiments of inventive concepts have been particularly shown and described, it will be understood by one of ordinary skill in the art that variations in form and detail may be made therein without departing from the spirit and scope of the claims.

What is claimed is:

1. A semiconductor device, comprising:
a lower active portion protruding from a substrate;
a plurality of active pillars protruding from the lower active portion;
surround gate electrodes surrounding the plurality of active pillars, respectively,
the surround gate electrodes being spaced apart from each other;
a buried bit line extending between at least two pairs of neighboring surround gate electrodes,
the buried bit line extending along a first direction and being electrically connected to the lower active portion; and
a plurality of contact gate electrodes,
each contact gate electrode contacting both of one of the surround gate electrodes and one of a plurality of word lines extending along a second direction crossing the first direction.

2. The device of claim 1, wherein, in a plan view, the lower active portion has one of a ‘T’-shape, a cross-like shape, and a diamond-like shape.

3. The device of claim 1, wherein
the plurality of contact gate electrodes are between adjacent twosomes of the surround gate electrodes, respectively, and
each one of the plurality of contact gate electrodes is in contact with the surround gate electrodes of one of the adjacent twosomes of the surround gate electrodes.

4. The device of claim 1, wherein
a top surface of at least one of the plurality of active pillars is higher than a top surface of at least one of the surround gate electrodes, and
each one of the plurality of active pillars include an upper doped region above a channel region.

5. The device of claim 1, further comprising:
a lower doped region in the lower active portion, wherein
the lower doped region is electrically connected to the buried bit line.

6. The device of claim 5, wherein the lower doped region does not vertically overlap the upper doped region.

7. The device of claim 5, wherein
the buried bit line contacts the lower active portion, and
the lower doped region is in the lower active portion below the buried bit line.

8. The device of claim 5, further comprising:
a bit line node contact between the buried bit line and the lower active portion,
wherein the lower doped region is in the lower active portion below the bit line node contact.

9. The device of claim 8, wherein
the semiconductor device includes a plurality of lower active portions, a plurality of buried bitlines, and a plurality of bitline node contacts, and
each bitline node contact is between one of the plurality of the lower active portions and one of the plurality of the buried bit lines.

10. The device of claim 1, further comprising:
a plurality of storage node pads on the plurality of active pillars, respectively,
wherein a width of the plurality of storage node pads is greater than a width of the plurality of active pillars.

11. The device of claim 10, wherein
at least one of the plurality of storage node pads includes a first side parallel to the first direction and a second side parallel to the second direction,
the second side being longer than the first side.

12. The device of claim 1, further comprising:
a plurality of gate insulating layers, wherein
the plurality of gate insulating layers are between the plurality of surround gate electrodes and the plurality of active pillars, respectively, and
the plurality of gate insulating layers are between the plurality of surround gate electrodes and the lower active portion.

13. The device of claim 1, wherein
the semiconductor device includes a plurality of lower active portions and a device isolation layer between the plurality of lower active portions.

14. The device of claim 1, wherein
the lower active portion has a ‘T’ shape in a plan view, and
the buried bit line vertically overlaps an end portion of the lower active portion.

15. A semiconductor device, comprising:
a lower active portion protruding from a substrate;
an active pillar protruding from the lower active portion;
a surround gate electrode surrounding the active pillar;
a buried bit line extending along a first direction,
the buried bit line being on the lower active portion and electrically connected to the lower active portion; and
a contact gate electrode contacting both the surround gate electrode and a word line extending a second direction crossing the first direction.

16. A semiconductor device, comprising:
a plurality of transistor pairs on a substrate, each transistor pair including,
a first active pillar surrounded by a first gate electrode,
a second active pillar spaced apart from the first active pillar and surrounded by a second gate electrode, and
a contact gate electrode connecting the first and second gate electrodes;
a plurality of impurity regions spaced apart in the substrate;
a plurality of bitlines intersecting a plurality of wordlines,
each bitline being connected to at least one of the impurity regions,
each bitline extending in a first direction between the first and second gate electrodes of at least one of the transistor pairs, and
each wordline line being connected to at least one contact gate electrode of the plurality of transistor pairs.

17. The semiconductor device of claim 16, wherein
the substrate includes a plurality of active portions spaced apart and protruding from the substrate,
each of the plurality of active portions contains one of the impurity regions,
each of the plurality of active portions connects one of an adjacent two of the first active pillars and an adjacent two of the second active pillars.

18. The semiconductor device of claim 17, further comprising:
an isolation layer between the plurality of active portions, wherein
each contact gate electrode of the plurality of transistor pairs is over the isolation layer.

19. The semiconductor device of claim 16, wherein
the plurality of transistor pairs includes a first transistor pair and a second transistor pair, and
one of the plurality of impurity regions is connected through the substrate to the first active pillar of the first transistor pair and the first active pillar of the second transistor pair.

20. The semiconductor device of claim 16, wherein
each of the plurality of transistor pairs includes a gate oxide layer that extends between the first active pillar and the first gate electrode and between the second active pillar and the second gate electrode,
each of the first active pillars of the plurality of transistor pairs include a doped region above a channel region, and
the first gate electrodes in each of plurality of transistor pairs surrounds the channel regions but not the doped regions of the first active pillars.
